(19) United States
(12) Patent Application Publication
(10) Pub. No.: US 2026/0013359 A1
(43) Pub. Date: Jan. 8, 2026

(54) Display Panel and Display Apparatus

(71) Applicant: BOE TECHNOLOGY GROUP CO., LTD., Chaoyang District, Beijing (CN)

(72) Inventors: Wenxiu Zhu, Beijing (CN); Lujiang Huangfu, Beijing (CN); Hongli Wang, Beijing (CN); Hualing Yang, Beijing (CN)

(21) Appl. No.: 18/992,499

(22) PCT Filed: Jul. 13, 2023
(86) PCT No.: PCT/CN2023/107292

§ 371 Date: Jan. 8, 2025

(30) Foreign Application Priority Data
Jul. 29, 2022 (CN) 202210910962.5

(51) Int. Cl. H10K 59/35; H10H 29/34; H10H 29/37; H10H 29/49; H10H 29/85; H10H 29/855; H10K 59/122; H10K 59/126; H10K 59/131; H10K 59/38

(52) U.S. Cl. CPC H10K 59/353; H10H 29/345; H10H 29/37; H10H 29/49; H10H 29/8517; H10H 29/855; H10K 59/122; H10K 59/126; H10K 59/131; H10K 59/352; H10K 59/38

(57) ABSTRACT

A display panel includes a base substrate, data lines arranged, pixel driving circuits, a pixel definition layer, and pixels. The pixel definition layer includes pixel openings, the pixel openings include first pixel openings, second pixel openings and third pixel openings. A pixel includes sub-pixels that emit light of different colors. The sub-pixels include: a first sub-pixel located at a first pixel opening, a second sub-pixel located at a second pixel opening, and a third sub-pixel located at a third pixel opening. The first sub-pixel, the second sub-pixel and the third sub-pixel are sequentially arranged in a third direction. Each sub-pixel has a coupling point coupled to a pixel driving circuit. In a second direction, a distance between a geometric center of a coupling point of each of at least two sub-pixels that emit light of different colors and a respective pixel opening is different.

### CROSS-REFERENCE TO RELATED APPLICATIONS

This application is the United States national phase of International Patent Application No. PCT/CN2023/107292, filed Jul. 13, 2023, and claims priority to Chinese Patent Application No. 202210910962.5, filed Jul. 29, 2022, the disclosures of which are hereby incorporated by reference in their entireties.

### BACKGROUND OF THE INVENTION

### Field of the Invention

The present disclosure relates to the field of display technologies, and in particular, to a display panel and a display apparatus.

### Description of Related Art

Organic light-emitting diodes (OLEDs) have a series of advantages such as high brightness, full viewing angle, fast response, and flexible display. OLED display apparatuses can be divided into passive matrix OLED (PMOLED) apparatuses and active matrix OLED (AMOLED) apparatuses according to the driving mode. AMOLED display apparatuses have higher luminous efficiency and can be used as high-resolution and large-sized display apparatuses.

### SUMMARY OF THE INVENTION

In an aspect, a display panel is provided. The display panel includes: a base substrate, a plurality of data lines, a plurality of pixel driving circuits, a pixel definition layer disposed on the base substrate, and a plurality of pixels disposed on the base substrate. The plurality of data lines are arranged in a first direction and extend in a second direction. The first direction and the second direction intersect. The plurality of pixel driving circuits are arranged in an array in the first direction and the second direction. The pixel definition layer includes a plurality of pixel openings, and the plurality of pixel openings include first pixel openings, second pixel openings and third pixel openings. The plurality of pixels are arranged in M rows and N columns, a row includes N pixels arranged in the first direction, a column includes M pixels arranged in the second direction,M≥2, andN≥2. A pixel includes a plurality of sub-pixels that emit light of different colors; the plurality of sub-pixels include: a first sub-pixel located at a first pixel opening, a second sub-pixel located at a second pixel opening, and a third sub-pixel located at a third pixel opening; the first sub-pixel, the second sub-pixel and the third sub-pixel are sequentially arranged in a third direction, the third direction and each of the first direction and the second direction intersecting.

Each sub-pixel has a coupling point coupled to a pixel driving circuit. In the second direction, a distance between a geometric center of a coupling point of each of at least two sub-pixels that emit light of different colors and a respective pixel opening is different.

In some possible embodiments, the sub-pixel includes: a first electrode and a second electrode that are opposite to each other, and the first electrode of the sub-pixel is close to the base substrate. The first electrode includes a connection portion and a body portion that are connected as a whole; a pixel opening exposes at least a part of the body portion; the coupling point of the sub-pixel is located in a region where the connection portion is located; and connection portions corresponding to at least two sub-pixels that emit light of different colors have different maximum sizes in the second direction.

In some possible embodiments, at least one of the first pixel opening, the second pixel opening and the third pixel opening is a pixel opening with a chamfered portion.

In some possible embodiments, the first pixel opening and the second pixel opening are each a pixel opening with a chamfered portion. A chamfered portion of the first pixel opening and a chamfered portion of the second pixel opening are respectively located on sides, facing away from each other, of the first pixel opening and the second pixel opening.

In some possible embodiments, one of the first sub-pixel and the second sub-pixel is a red sub-pixel, and another of the first sub-pixel and the second sub-pixel is a green sub-pixel.

In some possible embodiments, the pixel opening with the chamfered portion has an axisymmetric structure, and a symmetry axis of the pixel opening with the chamfered portion is parallel to the third direction.

In some possible embodiments, the pixel opening with the chamfered portion further has a first sidewall and a second sidewall adjacent to the chamfered portion; the chamfered portion and the first sidewall form a first vertex angle, the chamfered portion and the second sidewall form a second vertex angle, and the first vertex angle is 0.9 to 1.1 times the second vertex angle.

In some possible embodiments, a shape of a lower end of the first pixel opening, the second pixel opening or the third pixel opening includes one or more shape types of rectangle, square, parallelogram, trapezoid, rhombus, pentagon, hexagon, octagon, ellipse, and circle.

In some possible embodiments, shapes of lower ends of the first pixel opening, the second pixel opening and the third pixel opening are approximately the same.

In some possible embodiments, an included angle between the third direction and the second direction is in a range of 40° to 50°.

In some possible embodiments, an area of the first pixel opening is less than an area of the second pixel opening, and the area of the second pixel opening is less than an area of the third pixel opening.

In some possible embodiments, the display panel further includes a light-shielding layer disposed on a side of the pixel definition layer away from the base substrate and a plurality of filter patterns. The light-shielding layer is provided therein with a plurality of filter openings, and the plurality of filter openings include first filter openings, second filter openings, and third filter openings. The plurality of filter patterns include first filter patterns, second filter patterns and third filter patterns. A first filter pattern, a second filter pattern and a third filter pattern are located in a first filter opening, a second filter opening and a third filter opening, respectively. In a thickness direction of the base substrate, the first filter opening, the second filter opening and the third filter opening are directly opposite to the first pixel opening, the second pixel opening and the third pixel opening, respectively.

In some possible embodiments, an orthogonal projection of the first pixel opening on the base substrate is located within an orthogonal projection of the first filter opening on the base substrate.

For example, an orthogonal projection of the second pixel opening on the base substrate is located within an orthogonal projection of the second filter opening on the base substrate.

For example, an orthogonal projection of the third pixel opening on the base substrate is located within an orthogonal projection of the third filter opening on the base substrate.

For example, an orthogonal projection of the first pixel opening on the base substrate is located within an orthogonal projection of the first filter opening on the base substrate; and an orthogonal projection of the second pixel opening on the base substrate is located within an orthogonal projection of the second filter opening on the base substrate.

For example, an orthogonal projection of the second pixel opening on the base substrate is located within an orthogonal projection of the second filter opening on the base substrate; and an orthogonal projection of the third pixel opening on the base substrate is located within an orthogonal projection of the third filter opening on the base substrate.

In some possible embodiments, the first sub-pixel is a red sub-pixel, the second sub-pixel is a green sub-pixel, and the third sub-pixel is a blue sub-pixel. A ratio of an area of the second pixel opening to an area of the second filter opening is greater than a ratio of an area of the first pixel opening to an area of the first filter opening, and is less than a ratio of an area of the third pixel opening to an area of the third filter opening.

In some possible implementations, an orthogonal projection of the first pixel opening on the base substrate coincides with an orthogonal projection of the first filter opening on the base substrate.

For example, an orthogonal projection of the second pixel opening on the base substrate coincides with an orthogonal projection of the second filter opening on the base substrate.

For example, an orthogonal projection of the third pixel opening on the base substrate coincides with an orthogonal projection of the third filter opening on the base substrate.

For example, an orthogonal projection of the first pixel opening on the base substrate coincides with an orthogonal projection of the first filter opening on the base substrate; and an orthogonal projection of the second pixel opening on the base substrate coincides with an orthogonal projection of the second filter opening on the base substrate.

For example, an orthogonal projection of the second pixel opening on the base substrate coincides with an orthogonal projection of the second filter opening on the base substrate; and an orthogonal projection of the third pixel opening on the base substrate coincides with an orthogonal projection of the third filter opening on the base substrate.

In some possible embodiments, a size of the first filter opening in the third direction is a first filter size, a size of the first pixel opening in the third direction is a first pixel size, and the first filter size is greater than the first pixel size.

A size of the second filter opening in the third direction is a second filter size, a size of the second pixel opening in the third direction is a second pixel size, and the second filter size is greater than the second pixel size.

A size of the third filter opening in the third direction is a third filter size, a size of the third pixel opening in the third direction is a third pixel size, and the third filter size is greater than the third pixel size.

In some possible embodiments, a size of the first filter opening in a fourth direction is a fourth filter size, the fourth direction and the third direction intersecting; a size of the first pixel opening in the fourth direction is a fourth pixel size; the fourth filter size is greater than or equal to the fourth pixel size; and a difference between the first filter size and the first pixel size is greater than a difference between the fourth filter size and the fourth pixel size.

For example, a size of the second filter opening in the fourth direction is a fifth filter size, and a size of the second pixel opening in the fourth direction is a fifth pixel size; the fifth filter size is greater than or equal to the fifth pixel size; and a difference between the second filter size and the second pixel size is greater than a difference between the fifth filter size and the fifth pixel size.

For example, a size of the third filter opening in the fourth direction is a sixth filter size, and a size of the third pixel opening in the fourth direction is a sixth pixel size; the sixth filter size is greater than or equal to the sixth pixel size; and a difference between the third filter size and the third pixel size is greater than a difference between the sixth filter size and the sixth pixel size.

For example, a size of the first filter opening in a fourth direction is a fourth filter size, the fourth direction and the third direction intersecting; a size of the first pixel opening in the fourth direction is a fourth pixel size; the fourth filter size is greater than or equal to the fourth pixel size; and a difference between the first filter size and the first pixel size is greater than a difference between the fourth filter size and the fourth pixel size. A size of the second filter opening in the fourth direction is a fifth filter size, and a size of the second pixel opening in the fourth direction is a fifth pixel size; the fifth filter size is greater than or equal to the fifth pixel size; and a difference between the second filter size and the second pixel size is greater than a difference between the fifth filter size and the fifth pixel size.

For example, a size of the second filter opening in the fourth direction is a fifth filter size, and a size of the second pixel opening in the fourth direction is a fifth pixel size; the fifth filter size is greater than or equal to the fifth pixel size; and a difference between the second filter size and the second pixel size is greater than a difference between the fifth filter size and the fifth pixel size. A size of the third filter opening in the fourth direction is a sixth filter size, and a size of the third pixel opening in the fourth direction is a sixth pixel size; the sixth filter size is greater than or equal to the sixth pixel size; and a difference between the third filter size and the third pixel size is greater than a difference between the sixth filter size and the sixth pixel size.

In some possible embodiments, in a case where the first filter opening has the first filter size and the fourth filter size, the second filter opening has the second filter size and the fifth filter size, and the third filter opening has the third filter size and the six filter size, the first pixel opening has the first pixel size and the fourth pixel size, the second pixel opening has the second pixel size and the fifth pixel size, and the third pixel opening has the third pixel size and the sixth pixel size:

the difference between the first filter size and the first pixel size, the difference between the second filter size and the second pixel size, the difference between the third filter size and the third pixel size, the difference between the fourth filter size and the fourth pixel size, the difference between the fifth filter size and the fifth pixel size, and the difference between the sixth filter size and the the sixth pixel size are each greater than or equal to 0 μm and less than or equal to 6 μm.

In some possible embodiments, in a case where the first filter opening has the first filter size and the fourth filter size, the second filter opening has the second filter size and the fifth filter size, and the third filter opening has the third filter size and the six filter size, the first pixel opening has the first pixel size and the fourth pixel size, the second pixel opening has the second pixel size and the fifth pixel size, and the third pixel opening has the third pixel size and the sixth pixel size:
the difference between the first filter size and the first pixel size, the difference between the second filter size and the second pixel size, and the difference between the third filter size and the third pixel size are each in a range of 2 μm to 6 μm.

For example, the difference between the fourth filter size and the fourth pixel size, the difference between the fifth filter size and the fifth pixel size, and the difference between the sixth filter size and the the sixth pixel size are each in a range of 0 μm to 4 μm.

For example, the difference between the first filter size and the first pixel size, the difference between the second filter size and the second pixel size, and the difference between the third filter size and the third pixel size are each in a range of 2 μm to 6 μm. The difference between the fourth filter size and the fourth pixel size, the difference between the fifth filter size and the fifth pixel size, and the difference between the sixth filter size and the the sixth pixel size are each in a range of 0 μm to 4 μm.

In some possible embodiments, the plurality of filter openings are arranged in a plurality of rows in a fourth direction, a row includes at least one filter opening unit, and a filter opening unit includes one of the first filter openings, one of the second filter openings, and one of the third filter openings. A first filter opening, a second filter opening and a third filter opening in the row are sequentially arranged in the third direction, and an included angle between the third direction and the second direction is in a range of 40° to 50°.

In some possible embodiments, a width of the light-shielding layer between two adjacent filter openings is greater than or equal to 10 μm.

In some embodiments, the display panel has a first display region and a second display region. The plurality of pixels include a plurality of first pixels located in the first display region and a plurality of second pixels located in the second display region. A distribution density of the plurality of first pixels is greater than or equal to a distribution density of the plurality of second pixels.

In some possible embodiments, two first pixel openings, two second pixel openings and two third pixel openings corresponding to a first pixel and a second pixel satisfy at least one of the following limitations: shapes of lower ends of the two first pixel openings belong to different shape types; shapes of lower ends of the two second pixel openings belong to different shape types; or shapes of lower ends of the two third pixel openings belong to different shape types.

In some possible embodiments, two first pixel openings, two second pixel openings and two third pixel openings corresponding to a first pixel and a second pixel satisfy at least one of the following limitations: shapes of lower ends of the two first pixel openings belong to a same shape type; shapes of lower ends of the two second pixel openings belong to a same shape type; or shapes of lower ends of the two third pixel openings belong to a same shape type.

In some possible embodiments, a lower end of at least one of a first pixel opening, a second pixel opening and a third pixel opening corresponding to a second pixel is approximately in a shape of an ellipse or a circle. Lower ends of a first pixel opening, a second pixel opening and a third pixel opening corresponding to a first pixel are each approximately in a shape of a polygon.

In another aspect, a display apparatus is provided. The display apparatus includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a front view of a display apparatus, in accordance with some embodiments;

FIG. 2 is a structural diagram of a display panel, in accordance with some embodiments;

FIG. 3A is a diagram showing a stacking relationship of a plurality of layers included in the display panel shown in FIG. 2;

FIG. 3B is a structural diagram of the active pattern layer in FIG. 3A;

FIG. 3C is a structural diagram of the first conductive pattern layer in FIG. 3A;

FIG. 3D is a structural diagram of the active pattern layer and the first conductive pattern layer in FIG. 3A;

FIG. 3E is a structural diagram of the third conductive pattern layer in FIG. 3A;

FIG. 3F is a structural diagram of the active pattern layer, the first conductive pattern layer, and the third conductive pattern layer in FIG. 3A;

FIG. 3G is an equivalent circuit diagram of a pixel driving circuit, in accordance with some embodiments;

FIG. 4A is a diagram showing an arrangement of a plurality of pixel openings in the pixel definition layer shown in FIG. 3A;

FIG. 4B is a diagram showing an arrangement of a plurality of pixels in the light-emitting device layer shown in FIG. 3A;

FIG. 5 is a structural diagram of a pixel in the light-emitting device layer shown in FIG. 3A;

FIG. 6 is a diagram showing an arrangement of a plurality of pixels in a light-emitting device layer in a comparative embodiment;

FIG. 7A is a schematic diagram of a display panel DP displaying a horizontal line in a comparative embodiment;

FIG. 7B is a schematic diagram of a display panel DP displaying a vertical line in a comparative embodiment;

FIG. 8A is a schematic diagram of a display panel DP displaying an oblique line in a comparative embodiment;

FIG. 8B is a schematic diagram of a display panel DP displaying another oblique line in a comparative embodiment;

FIG. 9A is a schematic diagram of a display panel DP displaying a horizontal line, in accordance with some embodiments;

FIG. 9B is a schematic diagram of a display panel DP displaying a vertical line, in accordance with some embodiments;

FIG. 10A is a schematic diagram of a display panel DP displaying an oblique line, in accordance with some embodiments;

FIG. 10B is a schematic diagram of a display panel DP displaying another oblique line, in accordance with some embodiments;

FIG. 10C is a structural diagram showing connections between sub-pixels and pixel driving circuits;

FIG. 10D is an alternative structural diagram of FIG. 10C;

FIG. 11A is an alternative structural diagram of FIG. 4A;

FIG. 11B is an alternative structural diagram of FIG. 4B;

FIG. 11C is a perspective view of the second pixel opening in FIG. 11A;

FIG. 11D is a structural diagram of a pixel opening with chamfered portions;

FIG. 12 is a schematic diagram of possible shapes of pixel openings of a display panel, in accordance with some embodiments;

FIG. 13A is another alternative structural diagram of FIG. 4A;

FIG. 13B is another alternative structural diagram of FIG. 4B;

FIG. 14 is a structural diagram of the light-emitting device layer in FIG. 3A;

FIG. 15A is an alternative structural diagram of FIG. 14;

FIG. 15B is an alternative structural diagram of FIG. 14;

FIG. 15C is an alternative structural diagram of FIG. 14;

FIG. 16 is a diagram showing an arrangement of a plurality of filter openings disposed in a light-shielding layer in the display panel shown in FIG. 3A;

FIG. 17 is a top view of filter patterns in the display panel shown in FIG. 3A;

FIG. 18 is a structural diagram of filter patterns, a light-shielding layer, an encapsulation layer and a light-emitting device layer related to a pixel in the display panel shown in FIG. 3A;

FIG. 19 is a schematic diagram showing orthogonal projections of filter openings and pixel openings on a base substrate in the display panel shown in FIG. 3A;

FIG. 20 is an alternative structural diagram of FIG. 19;

FIG. 21 is another alternative structural diagram of FIG. 19;

FIG. 22 is an alternative structural diagram of FIG. 20;

FIG. 23 is yet another alternative structural diagram of FIG. 19;

FIG. 24 is another alternative structural diagram of FIG. 20;

FIG. 25 is yet another alternative structural diagram of FIG. 19; and

FIG. 26 is yet another alternative structural diagram of FIG. 20.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

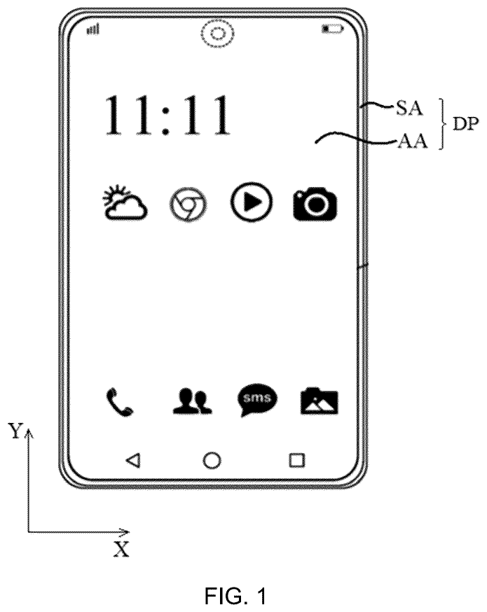

FIG. 1 is a front view of a display apparatus according to some embodiments. Referring to FIG. 1, embodiments of the present disclosure provide a display apparatus.

In some possible implementations, the display apparatus may be any apparatus that displays an image whether in motion (e.g., a video) or stationary (e.g., a still image), and whether textual or graphical. The display apparatus may be (but is not limit to), for example, a display, a television, a mobile telephone (e.g., cellphone), a wireless device, a personal digital assistant (PDA), a computer (e.g., hand-held or portable computer), a global positioning system (GPS) receiver/navigator, a camera, a moving picture experts group (MP4) video player, a video camera, a game console, a watch, a clock, a calculator, a monitor, a car display (e.g., odometer display, cockpit controller, cockpit display or rear view camera display in a vehicle), a navigator, a digital photo frame, an electronic billboard, an electronic signage, a projector, a building structure, a packaging and aesthetic structure (e.g., a display for an image of a piece of jewelry), etc.

In some possible implementations, referring to FIG. 1, the display apparatus includes a display panel DP. For example, the display apparatus may further include at least one of a frame, a display driver integrated circuit (DDIC), or a circuit board. The circuit board may be a flexible printed circuit (FPC) or a printed circuit board (PCB).

The circuit board may be coupled to the DDIC, and is configured to transmit electrical signals to the DDIC. The DDIC is configured to provide data signals to the display panel DP. For example, the DDIC is configured to generate the data signals based on the received electrical signals, and to transmit the data signals to the display panel DP. In addition, the display panel DP, DDIC and circuit board may be installed into the space enclosed by the frame.

The display panel DP is a screen with a display function, which can be coupled to the DDIC, and is configured to receive the data signals transmitted by the DDIC and display a corresponding image. For example, the display panel DP may be an organic light-emitting diode (OLED) display panel, a quantum dot light-emitting diode (QLED) display panel, a tiny light-emitting diode (LED) display panel (including a mini LED display panel or a micro LED display panel), etc.

With continued reference to FIG. 1, the display panel DP has a display region AA and a non-display region SA. The display region AA is a region of the display panel DP for displaying images. The non-display region SA is a region of the display panel DP other than the display region AA. The non-display region SA may be located on at least one side (e.g., one side or multiple sides) of the display region AA. For example, the non-display region SA may be disposed around the display region AA.

For example, a shape of the display region AA may be a rectangle, or may be a rectangle with rounded corners or other shapes similar to a rectangle. Based on this, the display region AA has two sides intersecting (e.g., being perpendicular to) each other. For convenience of description, a Cartesian coordinate system is established by taking extending directions of the two sides as X-axis and Y-axis respectively, where the X-axis and Y-axis can be interchanged.

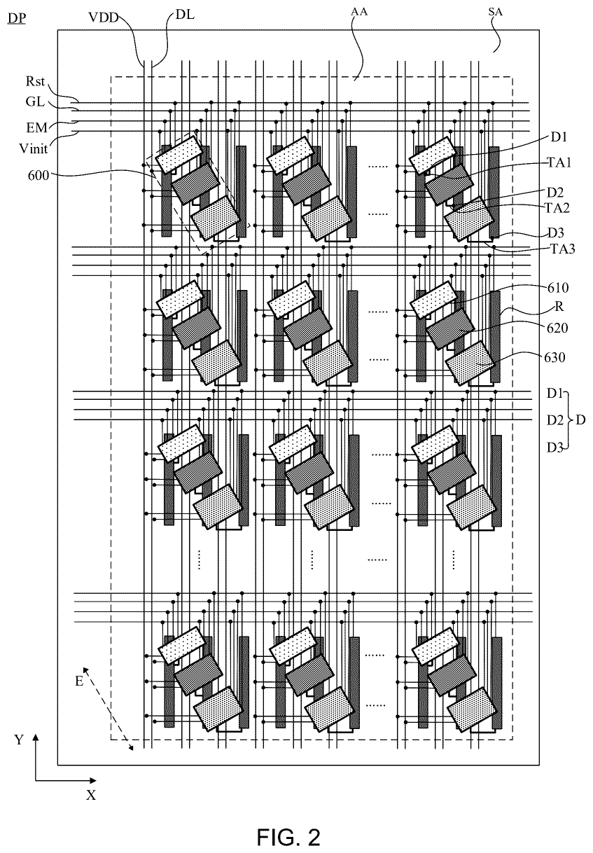

FIG. 2 is a structural diagram of a display panel according to some embodiments. Referring to FIG. 2, the display region AA of the display panel is provided therein with a plurality of pixels 600. The plurality of pixels 600 are arranged in M rows and N columns. A row includes N pixels 600 arranged in a first direction X, and a column includes M pixels 600 arranged in a second direction Y, where M is greater than or equal to 2 (M≥2), N is greater than or equal to 2 (N>2), and both M and N are integers. The first direction X and the second direction Y intersect, for example, are perpendicular to each other. For example, the first direction X is a direction indicated by the X-axis, so the reference sign of the X-axis is used. The second direction Y is a direction indicated by the Y-axis, so the reference sign of the Y-axis is used. For example, when the display panel DP displays a frame, pixels in the same row (including all sub-pixels in the pixels in the same row) may be driven (e.g., lit) at the same time, and pixels in different rows are driven in different time periods. For example, M rows of pixels may be driven row by row. For example, after a first row of pixels is driven, a second row of pixels is driven, and so on until an Mth row of pixels is driven.

A pixel (each pixel) 600 includes a plurality of sub-pixels. The sub-pixel is the smallest unit of the display panel for image display. Each sub-pixel may display a single color, such as red (R), green (G) or blue (B). The brightness (gray scale) of sub-pixels of different colors in each pixel 600 may be adjusted, and multiple colors may be displayed through color combination and superposition, thereby achieving full-color display of the display panel. For example, the pixel 600 may include a first sub-pixel 610, a second sub-pixel 620 and a third sub-pixel 630. The first sub-pixel 610, the second sub-pixel 620 and the third sub-pixel 630 emit light of different colors and are sequentially arranged in a third direction E. For example, the third sub-pixel 630 may be a blue sub-pixel; and among the first sub-pixel 610 and the second sub-pixel 620, one is a red sub-pixel and the other is a green sub-pixel. In some examples, the first sub-pixel 610 is a red sub-pixel, and the second sub-pixel is a green sub-pixel. Of course, colors of light emitted by the first sub-pixel 610 and the second sub-pixel 620 may be interchanged.

For example, a sub-pixel (each sub-pixel) P includes a light-emitting device. For example, the light-emitting device may be an OLED, a micro OLED, a QLED, a mini LED, or a micro LED. For example, the red sub-pixel may include a light-emitting device for emitting red light, the green sub-pixel may include a light-emitting device for emitting green light, and the blue sub-pixel may include a light-emitting device for emitting blue light.

In a pixel (each pixel) 600, the first sub-pixel 610, the second sub-pixel 620 and the third sub-pixel 630 are sequentially arranged in the third direction E. For example, the first sub-pixel 610, the second sub-pixel 620 and the third sub-pixel 630 of the pixel 600 are sequentially arranged from the upper left to the lower right of FIG. 2. For another example, the third sub-pixel 630, the second sub-pixel 620 and the first sub-pixel 610 of the pixel 600 are sequentially arranged from the upper left to the lower right of FIG. 2. The third direction E intersects both the first direction X and the second direction Y. For example, an angle between the third direction E and the second direction Y is in a range of 40° to 50°, such as one of 40°, 42°, 45°, 48°, and 50°.

The display panel DP may further include a plurality of pixel driving circuits R located in the display region AA. Each pixel driving circuit R may be coupled to a sub-pixel (e.g., a light-emitting device), and is configured to drive the sub-pixel to emit light.

The plurality of pixel driving circuits R may be arranged in an array, for example, arranged in M rows and C columns, where C is equal to W times N(C=W*N). Here, W is the number of sub-pixels included in one pixel. For example, in FIG. 2, one pixel includes three sub-pixels, then W is 3. The number of rows of the pixel driving circuits R and the number of rows of the pixels may be the same, which are both M. The number of columns of the pixel driving circuits R is W times the number of columns of the pixels. Each row (i.e., each row of pixel driving circuits R) includes C pixel driving circuits R arranged in the first direction X. The C pixel driving circuits R are respectively coupled to sub-pixels included in N pixels located in the same row. Pixel driving circuits R located in the same row may receive data signals simultaneously, so as to drive pixels located in the same row to emit light.

The pixel driving circuit R may include electronic elements such as a plurality of transistors and a capacitor. For example, each pixel driving circuit R may include three transistors and one capacitor, which constitute a 3T1C structure (i.e. one driving transistor, two switching transistors and one capacitor). Alternatively, each pixel driving circuit R may include more than three transistors and at least one capacitor, for example, 4T1C (i.e. one driving transistor, three switching transistors and one capacitor), 5T1C (i.e. one driving transistor, four switching transistors and one capacitor) or 7T1C (i.e. one driving transistor, six switching transistors and one capacitor), etc. The transistors may be thin film transistors (TFTs), field effect transistors (metal oxide semiconductors (MOSs)) or other switching devices with same characteristics.

In some embodiments of the present disclosure, the transistor may include a control electrode, a first electrode and a second electrode. The control electrode is a gate of the transistor, the first electrode is one of a source and a drain of the transistor, and the second electrode is another of the source and the drain of the transistor. Since the source and the drain of the transistor may be symmetrical in structure, the source and the drain of the transistor may be the same in structure. Therefore, the source of the transistor is referred to as the first electrode, or may be referred to as the second electrode.

In some embodiments, as shown in FIG. 2, the display panel DP may further include a plurality of signal lines. The signal lines may be coupled to the plurality of pixel driving circuits R, and are configured to transmit corresponding electrical signals to the pixel driving circuits R. The plurality of signal lines include a combination of one or more of a plurality of scan signal lines GL, a plurality of data lines DL, a plurality of reset signal lines Rst, a plurality of enable signal lines (also called light-emitting control signal lines) EM, a plurality of initialization signal lines Vinit, and a plurality of power supply voltage signal lines VDD.

For example, the plurality of scan signal lines GL, the plurality of enable signal lines EM and the plurality of initialization signal lines Vinit may be arranged in the first direction X, and the plurality of data lines DL and the plurality of power supply voltage signal lines VDD are arranged in the second direction Y. Each pixel driving circuit R may be electrically connected to the scan signal line GL, the data line DL, the reset signal line Rst, the enable signal line EM, the initialization signal line Vinit and the power supply voltage signal line VDD.

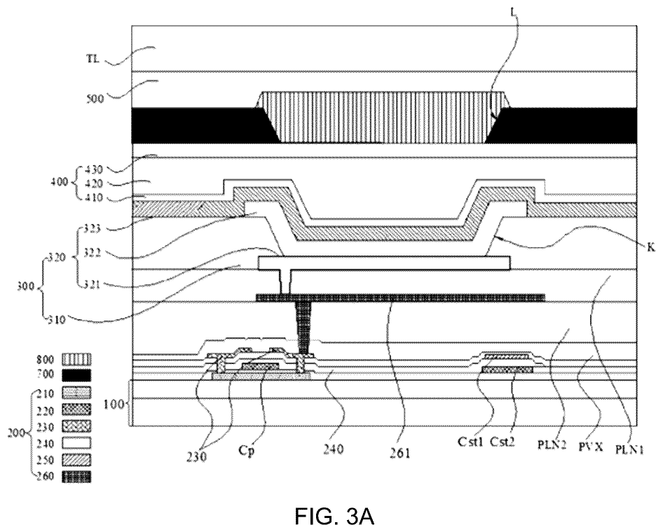

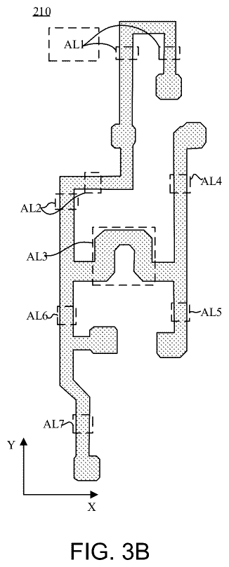

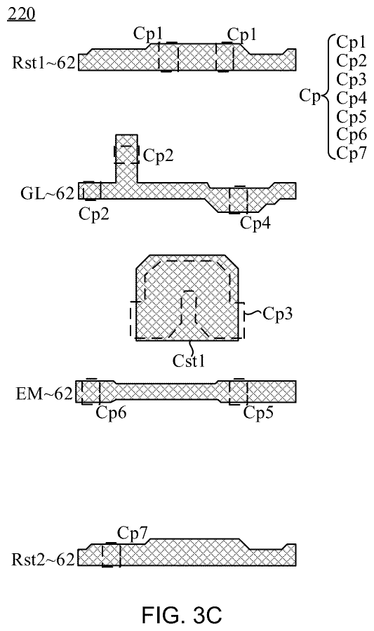

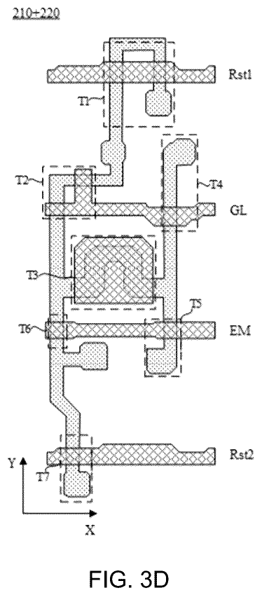

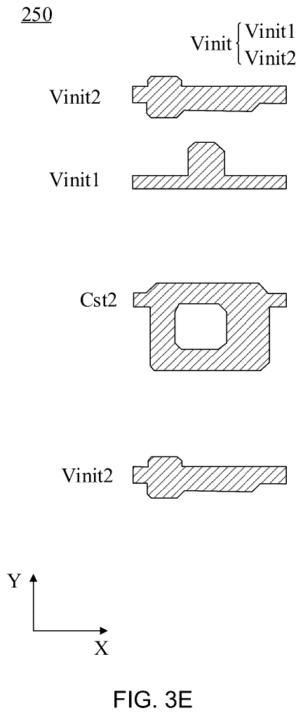

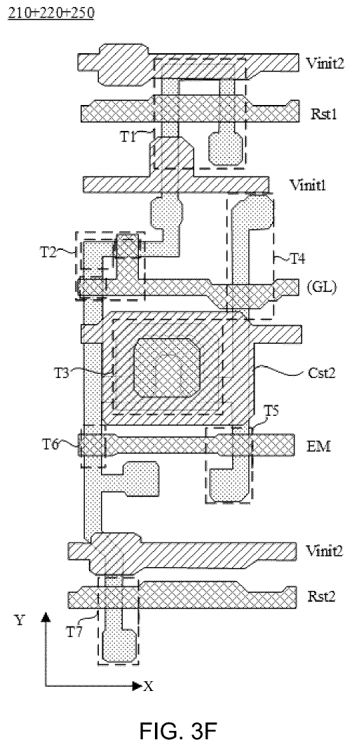

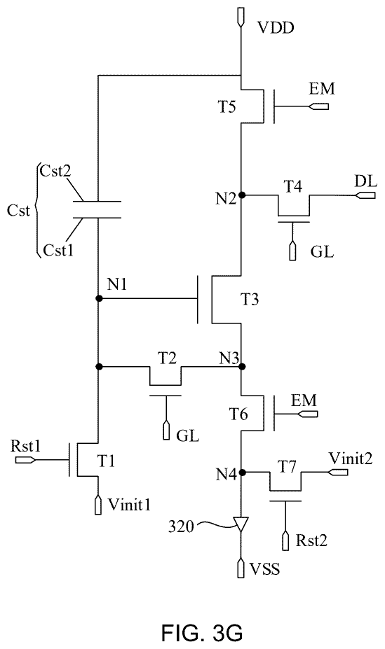

FIG. 3A is a diagram showing a stacking relationship of a plurality of layers included in the display panel shown in FIG. 2. In order to realize the structure (including the above-mentioned pixels, pixel driving circuits R and signal lines) shown in FIG. 2, for example, referring to FIG. 3A, the display panel DP includes: a base substrate 100, a pixel driving circuit layer 200 and a light-emitting device layer 300 that are stacked in sequence. The pixel driving circuit layer 200 includes the plurality of pixel driving circuits R as mentioned above. The light-emitting device layer 300 includes a plurality of light-emitting devices 320 for constituting a plurality of pixels 600.

A structure of the base substrate 100 may be set according to actual needs. The plurality of pixels 600 are disposed on the base substrate 100 (shown in FIG. 3A).

For example, the base substrate 100 may be a rigid base. The rigid substrate may be, for example, a glass base or a polymethyl methacrylate (PMMA) base. In this case, the display panel DP may be a rigid display panel.

For another example, the base substrate 100 may be a flexible base. The flexible base may be, for example, a polyethylene terephthalate (PET) base, a polyethylene naphthalate (PEN) base, or a polyimide (PI) base. In this case, the display panel 100 may be a flexible display panel.

The base substrate 100 may be of a single-layer structure or a multi-layer structure. For example, the base substrate may include at least one flexible base and at least one buffer layer, and the flexible base(s) and the buffer layer(s) are alternately stacked. For example, with continued reference to FIG. 3A, the pixel driving circuit layer 200 may include: an active pattern layer 210, a first conductive pattern layer 220, and a second conductive pattern layer 230 that are stacked in sequence. The pixel driving circuit layer 200 may further include insulating layers 240 that separate these pattern layers. These layers may constitute the plurality of pixel driving circuits R.

In the embodiments of the present disclosure, the term “pattern layer” may be of a layer structure that includes specific patterns and is formed by performing a patterning process on at least one film layer, which is formed by using a same film forming process. Depending on different specific patterns, the patterning process may include several coating, exposure, development or etching processes, and the specific patterns in the formed layer structure may be continuous or discontinuous, and these specific patterns may also be at different heights (or have different thicknesses). The “conductive pattern layer” is a pattern layer with conductive properties, which is made of a conductive material. For example, the “conductive pattern layer” is made of a transparent conductive material. For example, the transparent conductive material may be selected from at least one of indium tin oxide (ITO), aluminum-doped zinc oxide (AZO), etc., which can both conduct electricity and have a relatively high light transmittance in a range of visible light. The “conductive pattern layer” may also be made of a metal material, such as at least one of aluminum (AI), silver (Ag), copper (Cu), chromium (Cr), etc.

FIG. 3B is a structural diagram of the active pattern layer in FIG. 3A. Referring to FIG. 3B, the active pattern layer 210 may be made of polysilicon (P-Si), and the active pattern layer 210 includes active patterns (which may also be called channel regions) of all transistors of the pixel driving circuit R. For example, the active patterns are a first active pattern AL1, a second active pattern AL2, a third active pattern AL3, a fourth active pattern AL4, a fifth active pattern AL5, a sixth active pattern AL6 and a seventh active pattern AL7.

The first conductive pattern layer 220 includes a plurality of gate patterns Cp. The second conductive pattern layer 230 includes a plurality of sources and a plurality of drains. An active pattern 211, a gate pattern Cp, a source and a drain that correspond to each other may constitute, for example, a transistor, and multiple transistors may constitute a pixel driving circuit R.

In addition, the pixel driving circuit layer may further include a third conductive pattern layer 250 located between the first conductive pattern layer 220 and the second conductive pattern layer 230. For example, the first conductive pattern layer 220 further includes a first plate Cst1, the third conductive pattern layer 250 further includes a second plate Cst2, and the first plate Cst1 and the second plate Cst2 are opposite to each other, so as to constitute the capacitor Cst of the pixel driving circuit R. In some other examples, the second plate Cst2 may also be included in the second conductive pattern layer 230.

FIG. 3C is a structural diagram of the first conductive pattern layer in FIG. 3A. FIG. 3D is a structural diagram of the active pattern layer and the first conductive pattern layer in FIG. 3A. Referring to FIGS. 3C and 3D, for example, the first conductive pattern layer 220 and the third conductive pattern layer 250 each include a plurality of signal lines. The first conductive pattern layer 220 includes a plurality of signal lines and the first plate Cst1 of the capacitor. The plurality of signal lines may be, for example, the scan signal lines GL, the reset signal lines Rst, and the enable signal lines EM. The plurality of signal lines located in the first conductive pattern layer 220 cross active patterns of the transistors. Overlapping portions of the plurality of signal lines located in the first conductive pattern layer 220 and the active patterns of the transistors are gate patterns Cp of the transistors.

For example, referring to FIGS. 3B to 3D, the first reset signal line Rst1 crosses the first active pattern AL1, and an overlapping portion of the first reset signal line Rst1 and the first active pattern AL1 is a first gate pattern Cp1.

The scan signal line GL crosses the second active pattern AL2 and the fourth active pattern AL4. An overlapping portion of the scan signal line GL and the second active pattern AL2 is a second gate pattern Cp2. An overlapping portion of the scan signal line GL and the fourth active pattern AL4 is a fourth gate pattern Cp4.

The first plate Cst1 crosses the third active pattern AL3, and an overlapping portion of the first plate Cst1 and the third active pattern AL3 is a third gate pattern Cp3.

The enable signal line EM crosses the fifth active pattern AL5 and the sixth active pattern AL6. An overlapping portion of the enable signal line EM and the fifth active pattern AL5 is a fifth gate pattern Cp5. An overlapping portion of the enable signal line EM and the sixth active pattern AL6 is a sixth gate pattern Cp6.

The second reset signal line Rst2 crosses the seventh active pattern AL7, and an overlapping portion of the second reset signal line Rst2 and the seventh active pattern AL7 is a seventh gate pattern Cp7.

FIG. 3E is a structural diagram of the third conductive pattern layer in FIG. 3A. Referring to FIG. 3E, in some embodiments, the third conductive pattern layer 250 includes a plurality of signal lines and the second plate Cst2 of the capacitor. The plurality of signal lines include the initialization signal lines Vinit. The initialization signal lines Vinit include first initialization signal lines Vinit1 and second initialization signal lines Vinit2.

It will be noted that “cross” in the present disclosure means that an orthogonal projection of the former on the base substrate overlaps with an orthogonal projection of the latter on the base substrate. For example, each signal line in the first conductive pattern layer 220 crosses an active pattern of a corresponding transistor, which means that for each signal line of the first conductive pattern layer 220, for example, it may be that an orthogonal projection of the scan signal line GL (not shown in the figure) on the base substrate overlaps with an orthogonal projection of the second active pattern AL2 (not shown in the figure) on the base substrate.

Hereinafter, the pixel driving circuit R of a 7T1C mode is taken as an example for introduction.

FIG. 3F is a structural diagram of the active pattern layer, the first conductive pattern layer and the third conductive pattern layer in FIG. 3A. FIG. 3G is an equivalent circuit diagram of a pixel driving circuit R according to some embodiments. Referring to FIGS. 3F and 3G, for example, the pixel driving circuit R of the 7T1C mode includes: a first reset transistor T1, a compensation transistor T2, a driving transistor T3, a writing transistor T4, a first enable transistor T5, a second enable transistor T6, a second reset transistor T7, and a capacitor Cst.

A control electrode of the first reset transistor T1 is electrically connected to the first reset signal line Rst1. A first electrode of the first reset transistor T1 is electrically connected to the first initialization signal line Vinit1. A second electrode of the first reset transistor T1 is electrically connected to a first node N1.

A control electrode of the compensation transistor T2 is electrically connected to the scan signal line GL. A first electrode of the compensation transistor T2 is electrically connected to a third node N3. A second electrode of the compensation transistor T2 is electrically connected to the first node N1.

A control electrode of the driving transistor T3 is electrically connected to the first node N1. A first electrode of the driving transistor T3 is electrically connected to a second node N2. A second electrode of the driving transistor T3 is electrically connected to the third node N3.

A first plate Cst1 of the capacitor Cst is electrically connected to the first node N1. A second plate Cst2 of the capacitor Cst is electrically connected to a first voltage signal terminal VDD. The first voltage signal terminal VDD is electrically connected to the power supply voltage signal line VDD.

A control electrode of the writing transistor T4 is electrically connected to the scan signal line GL. A first electrode of the writing transistor T4 is electrically connected to the data line DL. A second electrode of the writing transistor T4 is electrically connected to the second node N2.

A control electrode of the first enable transistor T5 is electrically connected to the enable signal line EM. A first electrode of the first enable transistor T5 is electrically connected to the power supply voltage signal line VDD. A second electrode of the first enable transistor T5 is electrically connected to the second node N2.

A control electrode of the second enable transistor T6 is electrically connected to the enable signal line EM. A first electrode of the second enable transistor T6 is electrically connected to the third node N3. A second electrode of the second enable transistor T6 is electrically connected to an anode of a light-emitting device 320.

A control electrode of the second reset transistor T7 is electrically connected to the second reset signal line Rst2. A first electrode of the second reset transistor T7 is electrically connected to the second initialization signal line Vinit2. A second electrode of the second reset transistor T7 is electrically connected to a connection point N4 of the second electrode of the second enable transistor T6 and the anode of the light-emitting device 320. A cathode of the light-emitting device 320 is electrically connected to a second voltage signal terminal VSS. The second voltage signal terminal VSS transmits a low-level signal; for example, a voltage of the low-level signal may be zero.

The specific working process of the above transistors may be as follow. In a data writing period, the compensation transistor T2 and the writing transistor T4 are turned on under control of a scan signal received at the scan signal line GL, so that a data signal received at a data signal terminal is written into the first node N1 to compensate for the threshold voltage of the driving transistor T3. When the compensation transistor T2 and the writing transistor T4 are turned off, a voltage of the first node N1 is a sum of the data signal and the threshold voltage of the driving transistor T3. The voltage of the first node N1 can control a magnitude of a driving current passing through the driving transistor T3. In a light-emitting period, the compensation transistor T2 and the writing transistor T4 are turned off under control of the scan signal, and the first enable transistor T5 and the second enable transistor T6 are turned off under control of the enable signal received at the enable signal line EM. The driving transistor T3 is turned on and generates the driving current, and transmits the driving current to the light-emitting device 320. The light-emitting device 320 emits light under control of the driving current. The magnitude of the driving current affects the brightness of the light. That is to say, the voltage of the first node N1 may control the brightness of the light-emitting device 320, that is, it may control the gray scale of the sub-pixel, thus affecting the quality of the entire display image.

It will be noted that the first node N1, the second node N2 and the third node N3 in the embodiments of the present disclosure do not represent actual existing components, but represent junction points of relevant circuit connections in the layout of the pixel driving circuit R, That is, the first node N1, the second node N2 and the third node N3 are nodes equivalent to the junction points of electrical connections of relevant lines in the circuit diagram.

With continued reference to FIG. 3A, the light-emitting device layer 300 may further include a pixel definition layer 310 and a plurality of light-emitting devices 320. The pixel definition layer 310 has a plurality of pixel openings K, and a pixel opening K defines a position of a light-emitting device 320.

For example, the light-emitting device 320 includes a first electrode (e.g. an anode) 321, a light-emitting layer 322, and a second electrode (e.g. a cathode) 323 that are stacked in sequence.

For example, a structure of the first electrode 321 may be a composite structure composed of a transparent conductive oxide film, a metal film, and a transparent conductive oxide film that are stacked in sequence. The transparent conductive oxide film is, for example, made of any one of indium tin oxide (ITO) and indium zinc oxide (IZO). The metal film is, for example, made of any one of gold (Au), silver (Ag), nickel (Ni) and platinum (Pt).

For another example, the first electrode 321 may be of a single-layer structure, and the single-layer structure may be made of any one of ITO, IZO, Au, Ag, Ni, and Pt.

With continued reference to FIG. 3A, for example, among the plurality of pixel openings K of the pixel definition layer 310, a pixel opening K exposes a part of a first electrode 321. At least a part of a light-emitting layer 322 is located in a pixel opening K and is electrically connected to a corresponding first electrode 321. That is, each light-emitting layer 322 is electrically connected to a corresponding first electrode 321 through part or all of the light-emitting layer 322 located in a corresponding pixel opening K.

Here, the arrangement manner of the light-emitting layer 322 is related to the fabricating process of the light-emitting layer 322. For example, when the light-emitting layer 322 is formed using an evaporation process, a part of the light-emitting layer 322 may be located in the corresponding pixel opening K, and another part of the light-emitting layer 322 overlaps the pixel definition layer 310 around the pixel opening K. Alternatively, the entire light-emitting layer 322 may be located in the corresponding pixel opening K. In the case where the light-emitting layer 322 is formed using an inkjet printing technology, the entire light-emitting layer 322 may be located in the corresponding pixel opening K.

With continued reference to FIG. 3A, for example, the second electrode 323 is located on a side of the pixel definition layer 310 away from the base substrate 100. Second electrodes 323 of all light-emitting devices may be electrically connected to each other to constitute a one-piece structure.

For example, the second electrode 323 may be made of any one of aluminum (Al), silver (Ag), and magnesium (Mg), or any one of magnesium-silver alloy and aluminum-lithium alloy.

Of course, the light-emitting device layer 300 may further include at least one of a hole injection layer, a hole transport layer and an electron blocking layer that are disposed between the first electrode 321 and the light-emitting layer 322, and at least one of an electron injection layer, an electron transport layer and a hole blocking layer that are disposed between the second electrode 323 and the light-emitting layer 322.

With continued reference to FIG. 3A, in some possible implementations, the display panel DP may further include: a first planarization layer PLN1 located between the light-emitting device layer 300 and the pixel driving circuit layer 200, and the first planarization layer PLN1 is in direct contact with the light-emitting device layer 300.

With continued reference to FIG. 3A, in the case where the display panel DP further includes the first planarization layer PLN1, the first electrodes 321 of the light-emitting devices 320 are disposed on a surface of the first planarization layer PLN1 away from the base substrate 100. A first electrode 321 of the light-emitting device layer 300 may penetrate through the first planarization layer PLN1 to be electrically connected to a pixel driving circuit R.

With continued reference to FIG. 3A, in some possible implementations, the display panel DP may further include: a fourth conductive pattern layer 260 located between the first planarization layer PLN1 and the pixel driving circuit layer 200. The fourth conductive pattern layer 260 may include a plurality of connection portions 261.

In the case where the pixel driving circuit layer 200 may further include the fourth conductive pattern layer 260, a first electrode 321 of a light-emitting device 320 may be electrically connected to a pixel driving circuit R through a connection portion 261.

With continued reference to FIG. 3A, in some possible implementations, the display panel DP may further include: a second planarization layer PLN2 and a passivation layer PVX located on a side of the pixel driving circuit layer 200 away from the base substrate 100. The second planarization layer PLN2 may be made of an organic insulating material. The passivation layer PVX may be made of an inorganic insulating material.

With continued reference to FIG. 3A, in some possible implementations, the display panel DP further includes an encapsulation layer 400 disposed on a side of the light-emitting device layer 300 away from the base substrate 100.

With continued reference to FIG. 3A, for example, the encapsulation layer 400 may include a first inorganic insulating layer 410, an organic insulating layer 420 and a second inorganic insulating layer 430 that are sequentially stacked.

For example, the first inorganic insulating layer 410 and the second inorganic insulating layer 430 may be made of an inorganic material of nitride, oxide, oxynitride, nitrate, carbide or any combination thereof. The organic insulating layer 420 may be made of acrylic, hexamethyldisiloxane, polyacrylate, polycarbonate, polystyrene or other materials.

With continued reference to FIG. 3A, in some possible implementations, the display panel DP further includes a light-shielding layer 700 and a filter pattern layer 800 disposed on the side of the pixel definition layer 310 away from the base substrate 100. The light-shielding layer 700 is provided therein with a plurality of filter openings L. The filter pattern layer 800 includes a plurality of filter patterns 810. A filter opening L corresponds to a filter pattern 810. That is to say, the filter opening L and the filter pattern 810 have an overlapping portion in a thickness direction of the display panel DP. The filter openings L are used to define positions of the filter patterns 810.

With continued reference to FIG. 3A, in some possible implementations, the display panel DP further includes a touch layer TL. In this case, the display panel DP is a touch display panel, which is a product having a touch function and an image display function. With continued reference to FIG. 3A, the touch layer TL is configured to provide touch signals, and the touch signals may reflect touch positions of a user on the display panel DP. The touch layer TL may be coupled to a touch chip to provide the touch signals to the touch chip.

In some possible implementations, the touch layer TL may be located on a display side of the display panel DP. The touch layer TL may be a component independent of the display panel DP. For example, the display panel DP and the touch layer TL are formed separately and then bonded together by an adhesive such as an optical adhesive. For example, the encapsulation layer 400 may be used as a display surface of the display panel DP. The touch layer TL may be formed on the encapsulation layer 400 through photolithography or other processes. For another example, the touch layer TL may also be a structure integrated on the display panel DP. For example, the display panel DP is used as a base, the touch layer TL is formed on the display surface of the display panel DP. In this case, the touch layer TL is in direct contact with the display surface of the display panel DP, or there may be other functional layers between the touch layer TL and the display surface of the display panel DP.

In some other possible implementations, the touch layer TL may be located inside the display panel. For example, the display panel includes a first substrate and a second substrate that are opposite to each other, and the touch layer TL may be located between the first substrate and the second substrate.

With continued reference to FIG. 3A, in some possible implementations, the display panel DP further includes a buffer layer 500. The buffer layer 500 is disposed on a side of the light-shielding layer 700 away from the base substrate 100. The touch layer TL is disposed on the buffer layer 500 and may be in contact with the buffer layer 500. The buffer layer 500 may be made of an organic insulating material or inorganic insulating material.

The light-emitting device layer in FIG. 3A will be described in detail below.

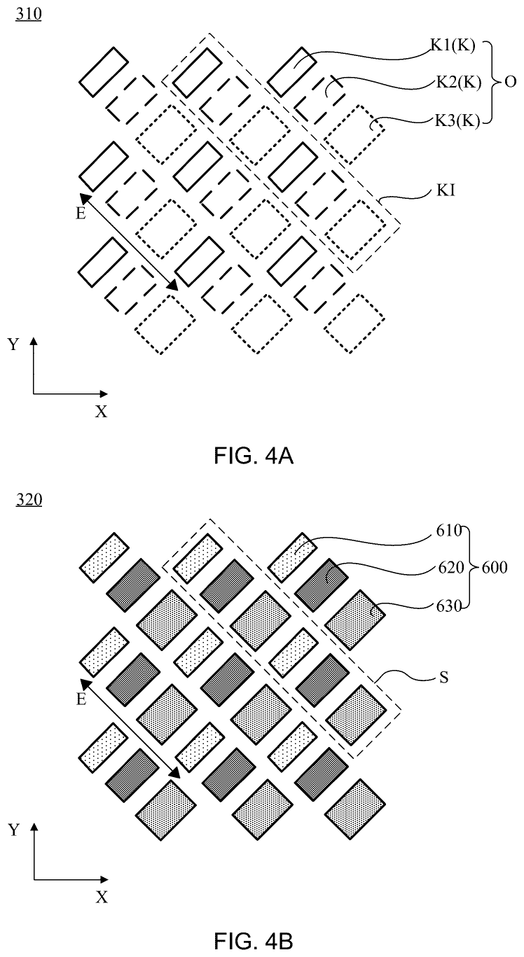

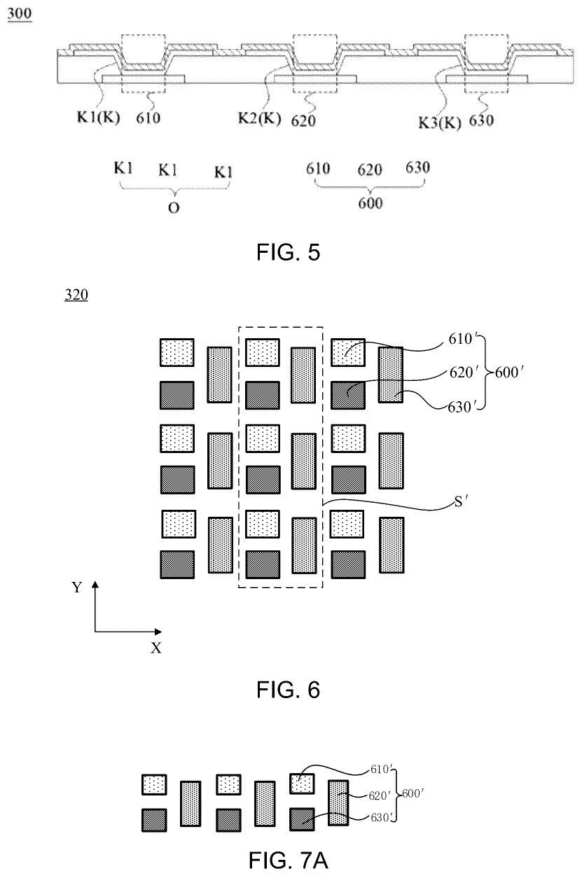

FIG. 4A is a diagram showing an arrangement of a plurality of pixel openings in the pixel definition layer shown in FIG. 3A. FIG. 4A shows a lower end of each pixel opening K. FIG. 4B is a diagram showing an arrangement of a plurality of pixels in the light-emitting device layer shown in FIG. 3A. FIG. 4B shows a light-emitting region of each sub-pixel in the pixel. FIG. 5 is a structural diagram of a pixel in the light-emitting device layer shown in FIG. 3A.

Referring to FIGS. 4A to 5, in the display panel DP mentioned above, the plurality of pixel openings K in the pixel definition layer 310 include a plurality of first pixel openings K1, a plurality of second pixel openings K2, and a plurality of third pixel openings K3. Based on the correspondence between one pixel opening K and the position of one sub-pixel, a group of pixel openings corresponding to a position of a pixel 600 is called an opening unit O herein. The pixel 600 includes a first sub-pixel 610 located at a first pixel opening K1, a second sub-pixel 620 located at a second pixel opening K2, and a third sub-pixel 630 located at a third pixel opening K3; and the first sub-pixel 610, the second sub-pixel 620 and the third sub-pixel 630 are sequentially arranged in the third direction E. Correspondingly, the opening unit O includes a first pixel opening K1, a second pixel opening K2 and a third pixel opening K3 that are sequentially arranged in the third direction E.

With continued reference to FIG. 4A, the plurality of pixel openings K may be divided into a plurality of opening groups KI, and all pixel openings K in each opening group KI are arranged in the third direction E. For example, each opening group KI is composed of an integer number of opening units O (i.e., at least one opening unit O, such as one opening unit O or multiple opening units O). In the case where an opening group KI includes a plurality of opening units O, these opening units O are arranged in a line in the third direction E.

For example, in opening units O located in the same row (all opening units corresponding to the pixels in the same row), pixel openings K of the same type are also located in the same row. For example, the first pixel openings K1 are arranged in the first direction X; similarly, the second pixel openings K2 are also arranged in the first direction X; and similarly, the third pixel openings K3 are also arranged in the first direction X. For another example, in opening units O located in the same column, pixel openings K of the same type are also located in the same column. For example, the first pixel openings K1 are arranged in the second direction Y; similarly, the second pixel openings K2 are also arranged in the second direction Y; and similarly, the third pixel openings K3 are also arranged in the second direction Y.

Referring to FIG. 4A, the embodiments of the present disclosure provide a display substrate DP. An area of the first pixel opening K1 of the display panel DP is less than an area of the second pixel opening K2 of the display panel DP, which means that an area of an orthogonal projection of the first pixel opening K1 on the base substrate 100 is less than an area of an orthogonal projection of the second pixel opening K2 on the base substrate 100; and an area of a lower end of the first pixel opening K1 is less than an area of a lower end of the second pixel opening K2. In addition, the area of the second pixel opening K2 is less than an area of the third pixel opening K3, which means that the area of the orthogonal projection of the second pixel opening K2 on the base substrate 100 is less than an area of an orthogonal projection of the third pixel opening K3 on the base substrate 100. Correspondingly, an area of an opening region of the first sub-pixel 610 is less than an area of an opening region of the second sub-pixel 620. The area of the opening region of the second sub-pixel 620 is less than an area of an opening region of the third sub-pixel 630.

With continued reference to FIG. 4B, the plurality of sub-pixels may be divided into a plurality of sub-pixel groups S, and all sub-pixels in each sub-pixel group S are arranged in the third direction E. For example, each sub-pixel group S is composed of an integer number of pixels 600 (i.e. at least one pixel 600, such as one pixel 600 or multiple pixels 600). In the case where a sub-pixel group S includes a plurality of pixels 600, these pixels 600 are arranged in a line in the third direction E.

FIG. 6 is a diagram showing an arrangement of a plurality of pixels in a light-emitting device layer in a comparative embodiment. Referring to FIG. 6, in a comparative embodiment, a plurality of pixels 600′ of a display panel DP (not shown in the figure) are arranged in the first direction X and the second direction Y to form M rows and N columns, each column includes multiple pixels 600′ that are arranged in the second direction Y, and a pixel 600′ (e.g., each pixel 600′) includes a red sub-pixel 610′, a green sub-pixel 620′ and a blue sub-pixel 630′. The red sub-pixel 610′ and the green sub-pixel 620′ are sequentially arranged in the second direction Y, and the blue sub-pixel 630′ is arranged on a side of the red sub-pixel 610′ and the green sub-pixel 620′ (e.g., a side to which the first direction X points). The sub-pixel group S′ extends in the second direction Y. Under the premise that an area of the blue sub-pixel 630′ in the pixel 600′ is constant, if the blue sub-pixel 630′ is made long and narrow (for example, a size of the blue sub-pixel 630′ in the second direction Y is the length, a size of the blue sub-pixel 630′ in the first direction X is the width; when the blue sub-pixel 630′ is made long and narrow, a ratio of its length to its width is large), the display effect will be affected. Therefore, the ratio of the length to the width of the blue sub-pixel 630′ needs to be made smaller. However, in this way, a distance between blue sub-pixels 630′ in the second direction Y becomes larger, causing the space of the distance not being utilized, which leads to a decrease in pixels per inch (PPI).

Referring to FIGS. 4A and 4B, in the embodiments, the first sub-pixel 610, the second sub-pixel 620 and the third sub-pixel 630 of the pixel 600 are arranged in sequence in the third direction E. A plurality of pixels arranged in the third direction E is a sub-pixel group S. In this way, a distance between two adjacent sub-pixels in a sub-pixel group S may be configured as needed. For example, a distance between the first sub-pixel 610 and the second sub-pixel 620 is approximately equal to a distance between the second sub-pixel 620 and the third sub-pixel 630. The distance between two adjacent sub-pixels may be approximately equal, or may not be equal. It can be seen that, in the embodiments, the distance between two adjacent sub-pixels will not be too large, so that the space may be fully utilized for the arrangement of sub-pixels, which improves the PPI.

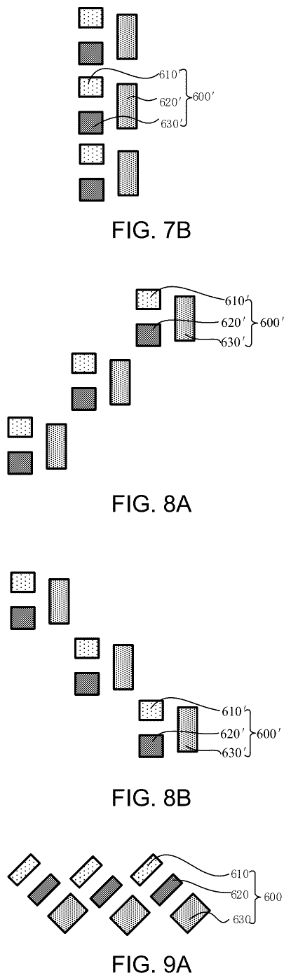

FIG. 7A is a schematic diagram of a display panel DP displaying a horizontal line in a comparative embodiment. Referring to FIG. 7A, in the comparative embodiment, when the display panel DP needs to display a horizontal line, at least one row (one row or multiple consecutive rows) of pixels corresponding to the horizontal line is lit by a row of pixel driving circuits R. Among multiple pixels 600′ in the row(s), there are first sub-pixels 610′ (e.g., red sub-pixels) and third sub-pixels 630′ (e.g., blue sub-pixels) close to an upper edge of the displayed horizontal line. However, human eyes are not sensitive to the recognition of blue (third sub-pixels 630′), and the third sub-pixels 630′ are farther from an upper edge than the first sub-pixels 610′; therefore, the upper edge of the displayed horizontal line will be reddish. There are second color pixels 620′ (e.g., green sub-pixels) and third sub-pixels 630′ (e.g., blue sub-pixels) close to the lower edge of the displayed horizontal line. However, human eyes are not sensitive to the recognition of blue (third sub-pixels 630′), and the third sub-pixels 630′ are farther from the lower edge than the green sub-pixel 620′; therefore, the lower edge of the displayed horizontal line will be greenish.

FIG. 7B is a schematic diagram of a display panel DP displaying a vertical line in a comparative embodiment. Referring to FIGS. 7A and 7B, in the comparative embodiments, since the human eyes have poor ability to recognize blue (e.g. the color of light emitted by the blue sub-pixels 630′), the human eyes can observe red (e.g. the color of light emitted by the red sub-pixels 610′) and green (e.g. the color of light emitted by the green sub-pixels 620′). In this way, when the horizontal line and the vertical line are displayed, the vertical line is relatively thin, and the horizontal line is relatively thick.

FIG. 8A is a schematic diagram of a display panel DP displaying an oblique line in a comparative embodiment. FIG. 8B is a schematic diagram of a display panel DP displaying another oblique line in a comparative embodiment. Referring to FIGS. 8A and 8B, in addition, in the comparative embodiments, when the display panel DP displays an oblique line, the displayed oblique line is composed of dots, and each dot is displayed by light emission of a pixel; in the comparative embodiments, the arrangement of the pixels causes a step between two adjacent pixels, so that the displayed oblique lines in the comparative embodiments will have a step-like shape.

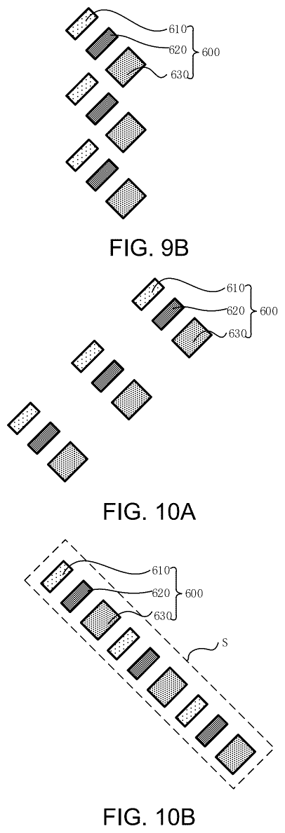

FIG. 9A is a schematic diagram of a display panel DP displaying a horizontal line according to some embodiments. Referring to FIG. 9A, in the embodiments, when the display panel DP displays a horizontal line, among multiple pixels 600 in a row, in addition to first sub-pixels 610 (e.g., red sub-pixels) at the upper edge of the displayed horizontal line, there are second sub-pixels 620 (e.g., green sub-pixels) slightly farther from the upper edge than the first sub-pixels 610. Moreover, human eyes are more sensitive to red and green. Therefore, when the horizontal line is displayed, both the first sub-pixels 610 and the second sub-pixels 620 can be viewed at the upper edge of the displayed horizontal line. Thus, there will be no reddish or greenish color cast at the upper edge of the displayed horizontal line. In addition, among multiple pixels 600 in a row, in addition to third sub-pixels 630 (e.g., blue sub-pixels) at the lower edge of the display horizontal line, there are second sub-pixels 620 (e.g., green sub-pixels) slightly farther from the lower edge than the third sub-pixels 630. Moreover, human eyes are not sensitive to blue, and the second sub-pixels 620 are slightly farther from the lower edge. Therefore, when the horizontal line is displayed, both the third sub-pixels 630 and the second sub-pixels 620 can be viewed at the lower edge of the displayed horizontal line. Thus, there will be no reddish or greenish color cast at the lower edge of the displayed horizontal line.

FIG. 9B is a schematic diagram of a display panel DP displaying a vertical line according to some embodiments. Referring to FIGS. 9A and 9B, in the embodiments, when the display panel DP displays a vertical line, since the human eyes are not sensitive to blue, red and green can be viewed. Therefore, widths of the displayed horizontal line and vertical line are the same.

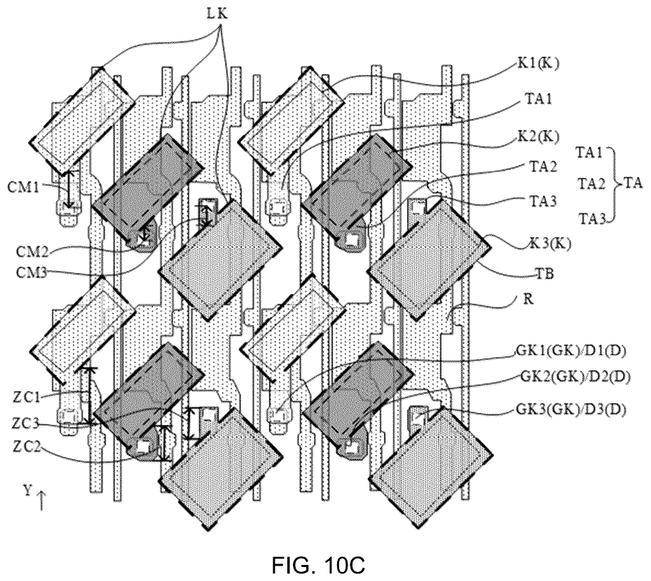

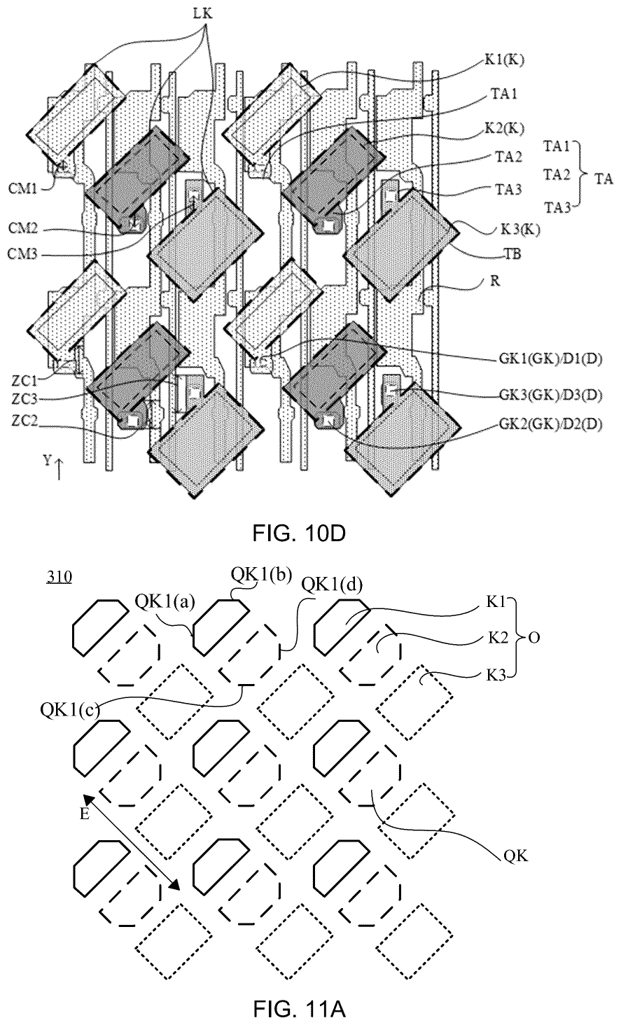

FIG. 10A is a schematic diagram of a display panel DP displaying an oblique line according to some embodiments. FIG. 10B is a schematic diagram of a display panel DP displaying another oblique line according to some embodiments. Referring to FIGS. 10A and 10B, in the embodiments, when the display panel DP displays an oblique line, since in a sub-pixel group S, first sub-pixels 610, second sub-pixels 620 and third sub-pixels 630 of a plurality of pixels 600 are all arranged in an oblique line display direction. Furthermore, the first sub-pixels 610, the second sub-pixels 620 and the third sub-pixels 630 have no overlapping portions in the oblique line display direction. Therefore, when the display panel DP displays an oblique line, the pixels 600 are continuous, and the displayed oblique line does not have a step-like shape.

It can be seen that in the embodiments, the arrangement of the pixels 600 can increase the area of the third sub-pixel 630, and in turn achieve the effect of increasing the aperture ratio of the third sub-pixel 630. In addition, when the display panel DP displays a horizontal line, there will be no reddish or greenish color cast at the edges of the displayed horizontal line. Moreover, when the display panel DP displays an oblique line, the pixels 600 are continuous, so that the displayed oblique line does not have a step-like shape.

FIG. 10C is a structural diagram showing connections between sub-pixels and pixel driving circuits. FIG. 10D is an alternative structural diagram of FIG. 10C. Referring to FIGS. 2, 3A, and 10C to 10D, in some possible implementations, each sub-pixel has a coupling point D coupled to a pixel driving circuit R. The sub-pixel includes a first electrode (e.g., an anode) 321 and a second electrode (e.g., a cathode) 323 that are opposite to each other. The first electrode 321 of the sub-pixel is close to the base substrate 100. The first electrode 321 of the sub-pixel and a corresponding pixel driving circuit R have an overlapping portion, and a via hole GK is provided in the overlapping portion (a via hole of the first sub-pixel 610 is marked as GK1, and a via hole of the second sub-pixel 620 is marked as GK2, and a via hole of the third sub-pixel 630 is marked as GK3). The first electrode 321 of the sub-pixel and the pixel driving circuit R are electrically connected at the position of the via hole GK. The coupling point D refers to the position of the via hole GK.

In the second direction Y, a distance between a geometric center (which may also be called a geometric center of gravity) of each coupling point D of at least two sub-pixels that emit light of different colors and a respective pixel opening K is different. The distance between the coupling point D and the pixel opening K refers to a distance, in the second direction Y, from the geometric center of the coupling point D to a point of the pixel opening K that is closest to the coupling point D. To facilitate the following description, the coupling point of the first sub-pixel 610 is marked as D1, the coupling point of the second sub-pixel 620 is marked as D2, and the coupling point of the third sub-pixel 630 is marked as D3. In the second direction Y, the distance between the coupling point D1 and the first pixel opening K1 is marked as CM1, the distance between the coupling point D2 and the second pixel opening K2 is marked as CM2, and the distance between the coupling point D3 and the third pixel opening K3 is marked as CM3. At least two of D1, D2 and D3 have different distances from their respective pixel openings (e.g., the first pixel opening K1, the second pixel opening K2, and the third pixel opening K3). For example, D1, D2 and D3 have different distances from their respective pixel openings K. As another example, as shown in FIG. 10C, CM1 is greater than CM2 and CM3, and CM2 and CM3 are approximately equal. As another example, as shown in FIG. 10D, CM3 is greater than CM1 and CM2, and CM1 and CM2 are approximately equal.

Referring to FIGS. 2, 3A, and 10C to 10D, in some possible implementations, the first electrode 321 includes a connection portion TA and a body portion TB that are connected as a whole. The pixel opening K exposes at least a part of the body portion TB. For example, orthogonal projections, on the base substrate 100, of a part of the body portion TB and the pixel opening K overlap, and orthogonal projections, on the base substrate 100, of another part of the body portion TB and the pixel opening K do not overlap. For another example, an orthogonal projection of the body portion TB on the base substrate is located within an orthogonal projection of the pixel opening K on the base substrate 100. The coupling point D of the sub-pixel is located in a region where the connection portion TA is located. The body portion TB has the same shape as the corresponding pixel opening K, and a contour line LK of the body portion TB is obtained by expanding the pixel opening K corresponding to the body portion TB outward by one circle. The contour line LK of the body portion TB is used as a boundary line between the connection portion TA and the body portion TB.

Connection portions TA corresponding to at least two sub-pixels that emit light of different colors (e.g., two or three of the first sub-pixel 610, the second sub-pixel 620 and the third sub-pixel 630 that emit light of different colors) have different maximum sizes in the second direction Y. In order to facilitate the following description, a connection portion corresponding to the first sub-pixel 610 is denoted as a first connection portion TA1, a connection portion corresponding to the second sub-pixel 620 is denoted as a second connection portion TA2, and a connection portion corresponding to the third sub-pixel 630 is denoted as a third connection portion TA3. A maximum size of the first connection portion TA1 in the second direction Y is denoted as a first maximum size ZC1, and a maximum size of the second connection portion TA2 in the second direction Y is denoted as a second maximum size ZC2, and a maximum size of the third connection portion TA3 in the second direction Y is denoted as a third maximum size ZC3. For example, as shown in FIG. 10C, the first maximum size ZC1 is greater than the second maximum size ZC2 and the third maximum size ZC3, and the second maximum size ZC2 and the third maximum size ZC3 are approximately equal. As another example, as shown in FIG. 10D, the third maximum size ZC3 is greater than the second maximum size ZC2 and the first maximum size ZC1, and the second maximum size ZC2 and the first maximum size ZC1 are approximately equal.

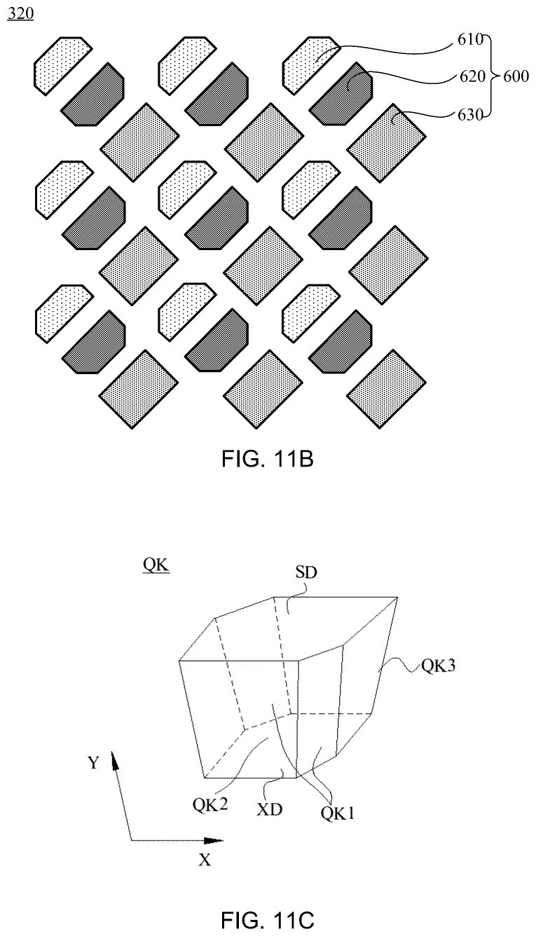

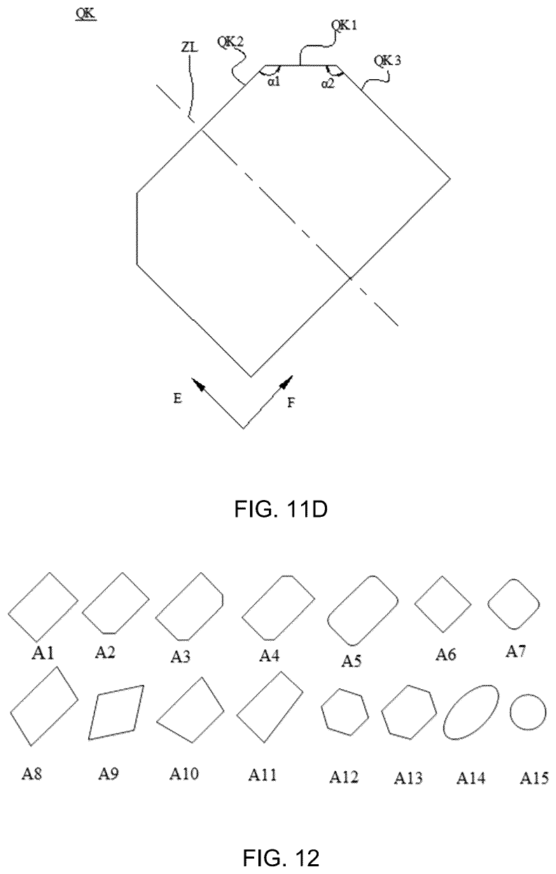

FIG. 11A is an alternative structural diagram of FIG. 4A. FIG. 11B is an alternative structural diagram of FIG. 4B. Referring to FIGS. 11A and 11B, some embodiments of the present disclosure provide a display substrate 100. In the display panel DP, at least one of the first pixel opening K1, the second pixel opening K2 and the third pixel opening K3 included in an opening unit O is a pixel opening with a chamfered portion. For the convenience of the following description, the pixel opening with a chamfered portion is called a chamfered opening QK. For example, among the first pixel opening K1, the second pixel opening K2 and the third pixel opening K3 included in an opening unit O, any one or two pixel openings are chamfered openings QK and the remaining pixel openings are not chamfered openings QK, or all three pixel openings are chamfered openings QK.

For example, FIG. 11C is a perspective view of the second pixel opening in FIG. 11A. Referring to FIG. 11C, the chamfered opening QK has a chamfered portion QK1. For example, a lower end XD of the chamfered opening QK is substantially in a shape of a polygon, and the chamfered portion QK1 of the chamfered opening QK makes at least one corner (e.g., one corner or multiple corners) of the polygon be recessed. For example, the lower end of the chamfered opening QK is substantially in a shape of a rectangle, which is recessed at two corners. The lower end XD of the chamfered opening QK refers to an end of a lower surface of the pixel opening K (e.g., the first pixel opening K1, or the second pixel opening K2, or the third pixel opening K3) for exposing the first electrode 321. An upper end SD of the chamfered opening QK refers to an end corresponding to an upper surface of the pixel opening K (e.g., the first pixel opening K1, or the second pixel opening K2, or the third pixel opening K3). Correspondingly, shapes of the upper end SD and the lower end XD of the chamfered opening QK are approximately the same. The chamfered portion QK1 of the chamfered opening QK also makes at least one corner (e.g., one corner or multiple corners) of the upper end SD be recessed.

For example, an orthogonal projection of the upper end SD of the chamfered opening QK on the base substrate covers an orthogonal projection of the lower end XD of the chamfered opening QK on the base substrate. That is, a size of the upper end SD of the chamfered opening QK is greater than a size of the lower end XD of the chamfered opening QK. Based on this, the chamfered portion QK1 of the chamfered opening QK is arranged obliquely.

In some examples, there are a plurality of continuous chamfered portions QK1, and the plurality of chamfered portions QK1 are connected end-to-end to form an arc-shaped edge. When edges of the first pixel opening K1, the second pixel opening K2 and the third pixel opening K3 of the display panel DP transition through arcs and there are less sharp vertex angles, a jagged visual effect of the first sub-pixel 610, the second sub-pixel 620 and the third sub-pixel 630 will be reduced.

With continued reference to FIGS. 11A and 11B, in some possible implementations, in an opening unit O, the first pixel opening K1 and the second pixel opening K2 are both chamfered openings QK. A chamfered portion QK1 of the first pixel opening K1 and a chamfered portion QK1 of the second pixel opening K2 are respectively located on sides, facing away from each other, of the first pixel opening K1 and the second pixel opening K2. To facilitate the following description, two chamfered portions of the first pixel opening K1 are referred to as a first chamfered portion QK (a) and a second chamfered portion QK (b). Two chamfered portions of the second pixel opening K2 are referred to as a third chamfered portion QK (c) and a fourth chamfered portion QK (d). The first pixel opening K1 may have one of the first chamfered portion QK (a) and the second chamfered portion QK (b), and the second pixel opening K2 may have the third chamfered portion QK (c) and the fourth chamfered portion QK (d). For example, the first pixel opening K1 has the first chamfered portion QK (a), and the second pixel opening K2 has the third chamfered portion QK (c). For another example, the first pixel opening K1 has the first chamfered portion QK (a), and the second pixel opening K2 has the fourth chamfered portion QK (d). Since the light-emitting region of each sub-pixel in the pixel and the corresponding pixel opening K in the opening unit O are approximately in the same shape, it may be possible to reduce sharp vertex angle(s) of the contour line of the pixel, and in turn reduce the jagged visual effect of the image displayed by the display panel.

Based on this, among the first sub-pixel 610 and the second sub-pixel 620, one is a red sub-pixel and the other is a green sub-pixel. For example, the first sub-pixel 610 is a red sub-pixel, and the second sub-pixel 620 is a green sub-pixel. As another example, the first sub-pixel 610 is a green sub-pixel, and the second sub-pixel 620 is a red sub-pixel. Since the human eyes are more sensitive to red and green than to blue, if pixel openings corresponding to the red sub-pixel and the green sub-pixel both have chamfered portions QK1, then the chamfered portions QK1 of the pixel openings may be respectively located on sides away from each other. In this way, it may further reduce the jagged visual effect of the image displayed by the display panel.

FIG. 11D is a structural diagram of a pixel opening with chamfered portions. Referring to FIG. 11D, in some possible implementations, the pixel opening (i.e., the chamfered opening) QK with chamfered portions has an axisymmetric structure. A symmetry axis ZL of the pixel opening (i.e., the chamfered opening) QK with chamfered portions is parallel to the third direction E. Correspondingly, the light-emitting region of the sub-pixel corresponding to the pixel opening (i.e., the chamfered opening QK) with chamfered portions may also has an axisymmetric structure.

With continued reference to FIG. 11D, in some possible implementations, the pixel opening (i.e., the chamfered opening QK) with chamfered portion(s) further has a first sidewall QK2 and a second sidewall QK3 adjacent to a chamfered portion QK1. The chamfered portion QK1 and the first sidewall QK2 form a first vertex angle α1, and the chamfered portion QK1 and the second sidewall QK3 form a second vertex angle α2. The first vertex angle α1 is 0.9 to 1.1 times the second vertex angle α2. A shape of an orthogonal projection, on the base substrate 100, of the pixel opening (chamfered opening) QK with the chamfered portions is axisymmetric, so that a shape of an orthogonal projection of a corresponding sub-pixel on the base substrate 100 is also axisymmetric, which leads to an artistic display effect of the display panel.

FIG. 12 is a schematic diagram of possible shapes of pixel openings of a display panel according to some embodiments. Referring to FIGS. 11A and 12, in some possible implementations, a shape of the lower end of the first pixel opening K1, the second pixel opening K2, or the third pixel opening K3 includes one or more shape types of rectangle (A1 to A5 in FIG. 12), square (A6 and A7 in FIG. 12), parallelogram (A8 and A9 in FIG. 12), rhombus (A9 in FIG. 12), trapezoid (A10 and A11 in FIG. 12), pentagon, hexagon, (A12 and A13 in FIG. 12), octagon, ellipse (A14 in FIG. 12) and circle (A15 in FIG. 12). For example, if a pixel opening K belongs to a shape type of rectangle, it means that the shape of the pixel opening K is approximately a rectangle; for example, it may be a standard rectangle (A1 in FIG. 12), or it may be a quasi-rectangle with a chamfer or rounded corner (A2 to A5 in FIG. 12). For another example, if a pixel opening K belongs to a shape type of square, it means that the shape of the pixel opening is approximately a square; for example, it may be a standard square (A6 in FIG. 12), or it may be a quasi-square with a chamfer or rounded corner (A7 in FIG. 12).

FIG. 12 shows some possible shapes of the pixel opening K, but the shape of the pixel opening K protected in the embodiments is limited thereto.

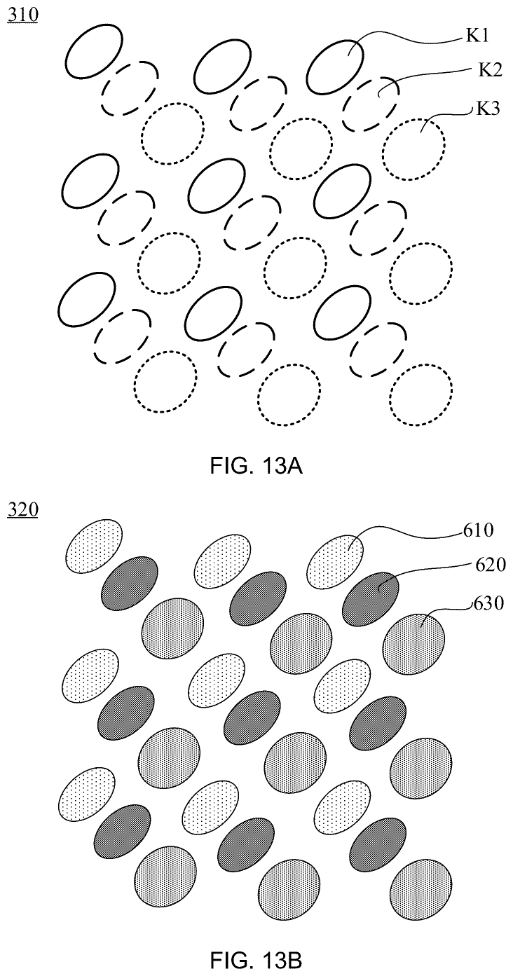

With continued reference to FIGS. 11A and 12, in some possible implementations, in an opening unit, the shapes of the lower ends of the first pixel opening K1, the second pixel opening K2 and the third pixel opening K3 belong to the same shape type. For example, the shapes of the first pixel opening K1, the second pixel opening K2, and the third pixel opening K3 are all square or rectangular (as shown in FIG. 4A). For another example, as shown in FIGS. 13A to 13B (FIG. 13A is another alternative structural diagram of FIG. 4A and FIG. 13B is another alternative structural diagram of FIG. 4B), the shapes of the first pixel opening K1, the second pixel opening K2 and the third pixel opening K3 are all elliptical.

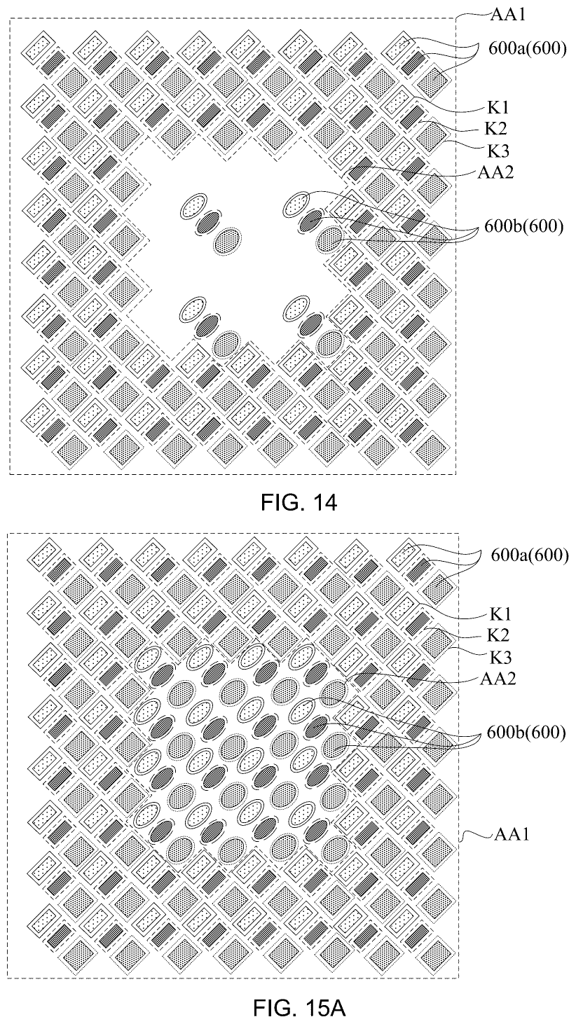

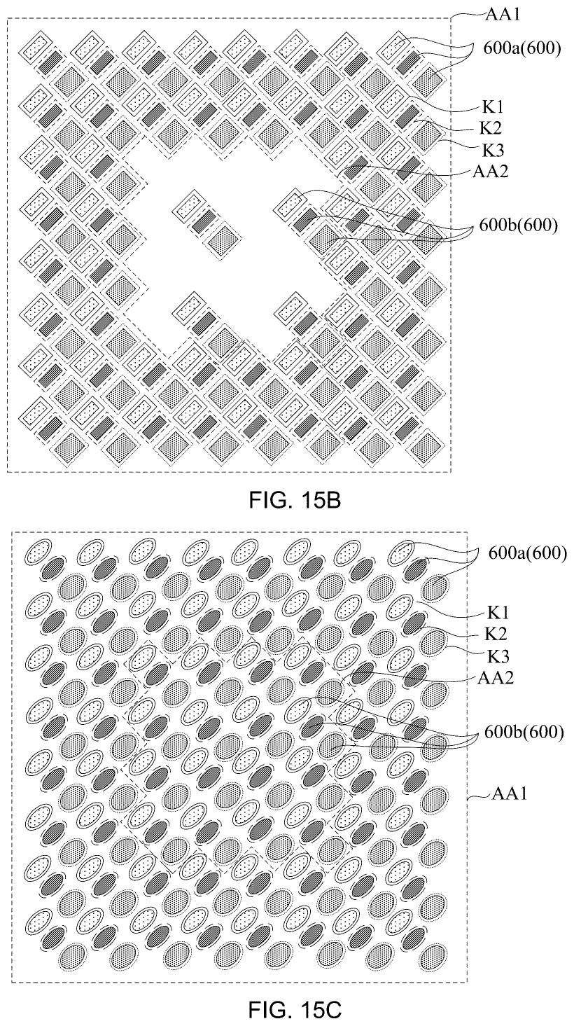

FIG. 14 is a structural diagram of the light-emitting device layer in FIG. 3A. FIG. 15A is an alternative structural diagram of FIG. 14. Referring to FIGS. 14 to 15A, some embodiments of the present disclosure provide a display panel DP. The display panel DP has a first display region AA1 and a second display region AA2. The first display region AA1 and the second display region AA2 are both located in the display region AA (shown in FIG. 1). For example, the first display region AA1 is a region other than the second display region AA2 in the display region AA. For example, the second display region AA2 is a region for setting an under-screen sensor. The display apparatus further includes a sensor disposed on a back side of the display panel, and the sensor is disposed directly opposite the second display region AA2. The sensor may be, for example, a camera, a distance sensor, etc.

The plurality of pixels 600 include first pixels 600a located in the first display region AA1 and second pixels 600b located in the second display region AA2. As shown in FIG. 14, a distribution density (i.e. a quantity distributed per unit area) of a plurality of first pixels 600a is greater than a distribution density of a plurality of second pixels 600b. Alternatively, as shown in FIG. 15A, the distribution density of the plurality of first pixels 600a is equal to the distribution density of the plurality of second pixels 600b.

Referring to FIGS. 14 to 15A, in some possible implementations, two first pixel openings K1, two second pixel openings K2 and two third pixel openings K3 corresponding to a first pixel 600a and a second pixel 600b satisfy at least one of the following limitations (i.e. conditions):
<X11>, shapes of lower ends of the two first pixel openings K1 belong to different shape types;
<X12>, shapes of lower ends of the two second pixel openings K2 belong to different shape types; or
<X13>, shapes of lower ends of the two third pixel openings K3 belong to different shape types.

As for a plurality of pixel openings corresponding to the first pixel 600a and the second pixel 600b that satisfy the limitations <X11>, <X12>, and <X13>, the following various examples are provided.

In an example N11, the plurality of pixel openings corresponding to the first pixel 600a and the second pixel 600b may satisfy the limitation <X11>, but do not satisfy the limitations <X12> and <X13>. That is to say, the shapes of lower ends of the two first pixel openings K1 corresponding to the first pixel 600a and the second pixel 600b belong to different shape types. The shapes of lower ends of the two second pixel openings K2 corresponding to the first pixel 600a and the second pixel 600b belong to the same shape type. The shapes of lower ends of the two third pixel openings K3 corresponding to the first pixel 600a and the second pixel 600b belong to the same shape type.

In an example N12, the plurality of pixel openings corresponding to the first pixel 600a and the second pixel 600b may satisfy the limitation <X12>, but do not satisfy the limitations <X11> and <X13>. As for details, reference may be made to the above explanation.

In an example N13, the plurality of pixel openings corresponding to the first pixel 600a and the second pixel 600b may satisfy the limitation <X13>, but do not satisfy the limitations <X12> and <X11>. As for details, reference may be made to the above explanation.

Example N14 is a combination of any two of the examples N11, N12 and N13.

Example N15 is a combination of the three examples N11, N12 and N13.

FIG. 15B is an alternative structural diagram of FIG. 14. FIG. 15C is an alternative structural diagram of FIG. 14. Referring to FIGS. 15B to 15C, in some other implementations, two first pixel openings K1, two second pixel openings K2 and two third pixel openings K3 corresponding to a first pixel 600a and a second pixel 600b satisfy at least one of the following limitations (i.e. conditions):
<X21>, shapes of lower ends of the two first pixel openings K1 belong to the same shape type;
<X22>, shapes of lower ends of the two second pixel openings K2 belong to the same shape type; or
<X23>, shapes of lower ends of the two third pixel openings K3 belong to the same shape type.

As for a plurality of pixel openings corresponding to the first pixel 600a and the second pixel 600b that satisfy the limitations <X21>, <X22>, and <X23>, the following various examples are provided.

In an example N21, the plurality of pixel openings corresponding to the first pixel 600a and the second pixel 600b may satisfy the limitation <X21>, but do not satisfy the limitations <X22> and <X23>. That is to say, the shapes of lower ends of the two first pixel openings K1 corresponding to the first pixel 600a and the second pixel 600b belong to the same shape type. The shapes of lower ends of the two second pixel openings K2 corresponding to the first pixel 600a and the second pixel 600b belong to different shape types. The shapes of lower ends of the two third pixel openings K3 corresponding to the first pixel 600a and the second pixel 600b belong to different shape types.

In an example N22, the plurality of pixel openings corresponding to the first pixel 600a and the second pixel 600b may satisfy the limitation <X22>, but do not satisfy the limitations <X21> and <X23>. As for details, reference may be made to the above explanation.

In an example N23, the plurality of pixel openings corresponding to the first pixel 600a and the second pixel 600b may satisfy the limitation <X23>, but do not satisfy the limitations <X22> and <X21>. As for details, reference may be made to the above explanation.

Example N24 is a combination of any two of the examples N21, N22 and N23.

Example N25 is a combination of the three examples N21, N22 and N23. With continued reference to FIGS. 14 to 15A, in some possible implementations, as for the light-emitting region of the sub-pixel and the pixel opening K where the sub-pixel is located, they may have the same shape, and may have the same size or different sizes. If they have the same size, then they are completely the same; in this case, their orthogonal projections on the pixel definition layer overlap. If they have different sizes, then the size of the light-emitting region of the sub-pixel may be greater than the size of the pixel opening; for example, the light-emitting region of the sub-pixel may be outwardly expanded by one circle relative to the pixel opening K, and the width of the expanded portion may be the same everywhere.

Correspondingly, light-emitting regions of two first sub-pixels 610, light-emitting regions of two second sub-pixels 620, and light-emitting regions of two third sub-pixels 630, which respectively correspond to the two first pixel openings K1, two second pixel openings K2 and two third pixel openings K3, need to satisfy at least one of the following limitations (i.e. conditions):
<X31>, shapes of the light-emitting regions of the two first sub-pixels 610 belong to different shape types;
<X32>, shapes of the light-emitting regions of the two second sub-pixels 620 belong to different shape types; or
<X33>, shapes of the light-emitting regions of the two third sub-pixels 630 belong to different pattern types.

As for the light-emitting regions of the two first sub-pixels 610, the light-emitting regions of the two second sub-pixels 620, and the light-emitting regions of the two third sub-pixels 630 that satisfy the limitations <X31>, <X32>, and <X33>, the following various examples are provided.

In an example N31, light-emitting regions of a plurality of sub-pixels corresponding to the first pixel 600a and the second pixel 600b may satisfy the limitation <X31>, but do not satisfy the limitations <X32> and <X33>. As for details, reference may be made to the above explanation.

In an example N32, the light-emitting regions of the plurality of sub-pixels corresponding to the first pixel 600a and the second pixel 600b may satisfy the limitation <X32>, but do not satisfy the limitations <X31> and <X33>. As for details, reference may be made to the above explanation.

In an example N33, the light-emitting regions of the plurality of sub-pixels corresponding to the first pixel 600a and the second pixel 600b may satisfy the limitation <X33>, but do not satisfy the limitations <X32> and <X31>. As for details, reference may be made to the above explanation.

Example N34 is a combination of any two of the examples N31, N32 and N33.

Example N35 is a combination of the three examples N31, N32 and N33.

With continued reference to FIGS. 14 to 15A, in some embodiments, in the display panel DP, a lower end of at least one (i.e. one, any two, or three) of the first pixel opening K1, the second pixel opening K2 and the third pixel opening K3 corresponding to the second pixel 600b is approximately in a shape of an ellipse or a circle. That is to say, an orthogonal projection, on the base substrate 100, of at least one of the first pixel opening K1, the second pixel opening K2 and the third pixel opening K3 corresponding to the second pixel 600b is in a shape of an ellipse or a circle. If the length and width of the sub-pixel corresponding to the second pixel 600b are constant, an area of the elliptical or circular light-emitting region of the sub-pixel is less than an area of the square light-emitting region of the sub-pixel, so that the area of the light-emitting region of the sub-pixel will be small. Therefore, an area of a non-light-emitting region is large. That is, a light-transmitting area is increased.

For example, among the first pixel opening K1, the second pixel opening K2 and the third pixel opening K3 corresponding to the second pixel 600b, lower ends of one or any two pixel openings are approximately elliptical or circular, and a lower end of the remaining pixel opening is neither elliptical nor circular.

For example, lower ends of the first pixel opening K1, the second pixel opening K2 and the third pixel opening K3 corresponding to the second pixel 600b are all approximately elliptical or circular. For another example, among the lower ends of the first pixel opening K1, the second pixel opening K2 and the third pixel opening K3 corresponding to the second pixel 600b, some are elliptical, and the rest are circular.

Lower ends of the first pixel opening K1, the second pixel opening K2 and the third pixel opening K3 corresponding to the first pixel are all approximately in a shape of polygon. For example, the polygon may be one of a rectangle, a square, a parallelogram, a trapezoid, a rhombus, a pentagon, and a hexagon.

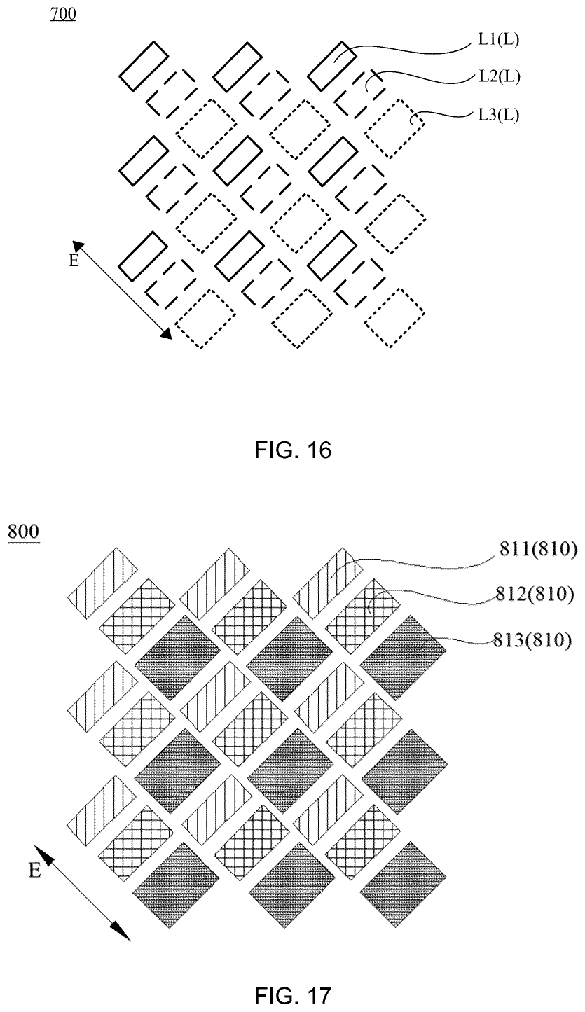

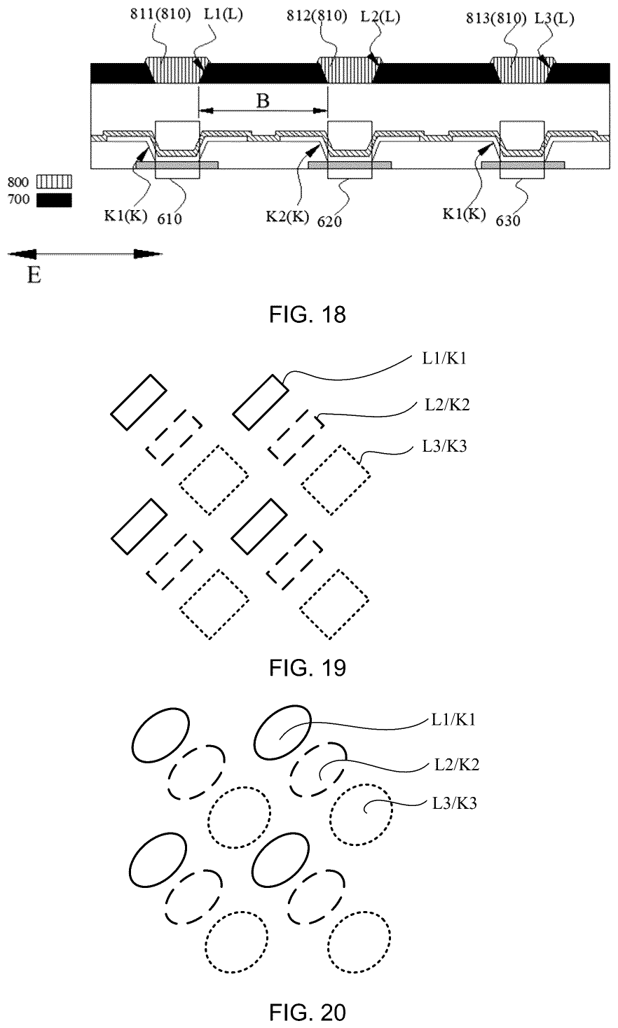

FIG. 16 is a diagram showing an arrangement of a plurality of filter openings disposed in a light-shielding layer in the display panel shown in FIG. 3A. FIG. 17 is a top view of filter patterns in the display panel shown in FIG. 3A. FIG. 18 is a structural diagram of filter patterns, a light-shielding layer, an encapsulation layer and a light-emitting device layer related to a pixel in the display panel shown in FIG. 3A.

Referring to FIGS. 3A and 16 to 18, in the display panel DP provided in some embodiments, the plurality of filter openings L in the light-shielding layer 700 include first filter openings L1, second filter openings L2 and third filter openings L3. The plurality of filter patterns 810 include first filter patterns 811, second filter patterns 812 and third filter patterns 813. The filter pattern 811, the second filter pattern 812 and the third filter pattern 813 are located in the first filter opening L1, the second filter opening L2 and the third filter opening L3, respectively. For example, a filter pattern 810 may cover a corresponding entire filter opening L. That is, an area of the filter pattern 810 may be greater than an area of an upper end of the filter opening L (an end of the filter opening L away from the base substrate 100).

In addition, in a thickness direction of the base substrate 100, the first filter opening L1, the second filter opening L2 and the third filter opening L3 are directly opposite to the first pixel opening K1, the second pixel opening K2 and the third pixel opening K3, respectively. Correspondingly, in the thickness direction of the base substrate 100, the first filter pattern 811, the second filter pattern 812 and the third filter pattern 813 are directly opposite to the light-emitting region of the first sub-pixel 610, the light-emitting region of the second sub-pixel 620, and the light-emitting region of the third sub-pixel 630, respectively. In this way, a filter pattern may act on most of light emitted by a corresponding sub-pixel, thereby obtaining a good filter effect. In addition, a color of light that the filter pattern allows to pass through is the same as a color of the light emitted by the corresponding sub-pixel. For example, the first filter pattern 811 is a red filter pattern, and the first sub-pixel 610 is a red sub-pixel. In this way, the light emitted by the sub-pixel can pass through the corresponding filter pattern, resulting in a high color purity.

Herein, “A is directly opposite to B in C direction” means that in the C direction, orthogonal projections of A and B on a plane perpendicular to the C direction overlap. For example, the first filter pattern 811 is directly opposite to the first sub-pixel 610 in the thickness direction of the base substrate 100, which means that orthogonal projections of the first filter pattern 811 and the first sub-pixel 610 on the base substrate 100 overlap.

Referring to FIG. 18, in some embodiments, in the third direction E, a distance B between two adjacent filter openings is greater than or equal to 10 μm (B ≥10 μm). For example, the distance B between two adjacent filter openings may be 10 μm, 10.5 μm, 11 μm, 12 μm, 13 μm, 14 μm or 15 μm. For example, the distance B between the first filter opening L1 and the second filter opening L2 is greater than or equal to 10 μm (B>10 μm). For another example, the distance B between the second filter opening L2 and the third filter opening L3 is greater than or equal to 10 μm (B ≥10 μm). For another example, the distance B between the third filter opening L3 and the first filter opening L1 is greater than or equal to 10 μm (B>10 μm). For example, the distance B between every two adjacent filter openings may be approximately equal, or may not be equal. FIG. 19 is a schematic diagram showing orthogonal projections of filter openings and pixel openings on a base substrate in the display panel shown in FIG. 3A. FIG. 20 is an alternative structural diagram of FIG. 19. Referring to FIGS. 19 and 20, in some embodiments, as for the size relationship between the filter opening L and the pixel opening K, the following various examples are provided.

In an example M11, the orthogonal projection of the first pixel opening K1 on the base substrate 100 coincides with the orthogonal projection of the first filter opening L1 on the base substrate 100. That is to say, the lower end of the first pixel opening K1 and the lower end of the first filter opening L1 have approximately the same shape, and have approximately the same size.

In an example M12, the orthogonal projection of the second pixel opening K2 on the base substrate 100 coincides with the orthogonal projection of the second filter opening L2 on the base substrate 100. That is to say, the lower end of the second pixel opening K2 and the lower end of the second filter opening L2 have approximately the same shape, and have approximately the same size.

In an example M13, the orthogonal projection of the third pixel opening K3 on the base substrate coincides with the orthogonal projection of the third filter opening L3 on the base substrate 100. That is to say, the lower end of the third pixel opening K3 and the lower end of the third filter opening L3 have approximately the same shape, and have approximately the same size.

Example M14 is a combination of any two of the examples M11, M12 and M13. Example M15 is a combination of the three examples M11, M12 and M13.

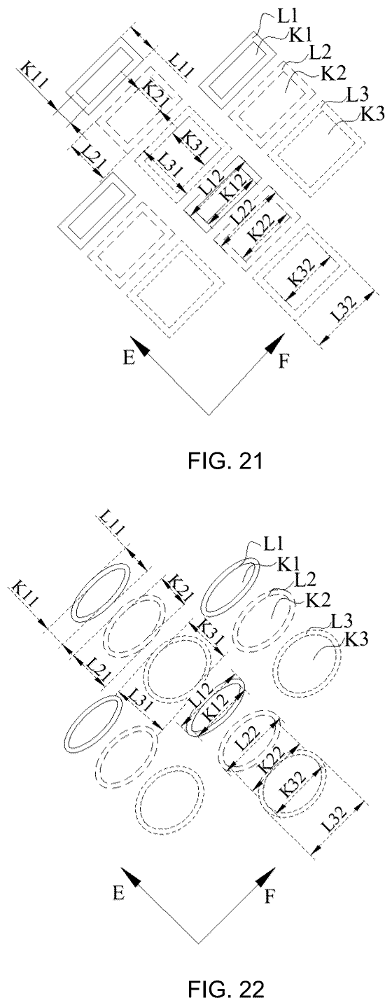

FIG. 21 is another alternative structural diagram of FIG. 19. FIG. 22 is an alternative structural diagram of FIG. 20. Referring to FIGS. 21 and 22, some embodiments of the present disclosure provide a display panel DP. In the display panel DP, the first pixel opening K1, the second pixel opening K2 and the third pixel opening K3 may satisfy at least one of the following limitations (i.e. conditions):
<X41>, the orthogonal projection of the first pixel opening K1 on the base substrate 100 (not shown in the figure) is located within the orthogonal projection of the first filter opening L1 on the base substrate 100; that is, the size of the lower end of the first pixel opening K1 is less than the size of the lower end of the first filter opening L1;
<X42>, the orthogonal projection of the second pixel opening K2 on the base substrate 100 is located within the orthogonal projection of the second filter opening L2 on the base substrate 100; that is, the size of the lower end of the second pixel opening K2 is less than the size of the lower end of the second filter opening L2; or
<X43>, the orthogonal projection of the third pixel opening K3 on the base substrate 100 is located within the orthogonal projection of the third filter opening L3 on the base substrate 100; that is, the size of the lower end of the third pixel opening K3 is less than the size of the lower end of the third filter opening L3.

As for the first pixel opening K1, the second pixel opening K2 and the third pixel opening K3 that satisfy the limitations <X41>, <X42>, and <X43>, the following various examples are provided.

In an example N41, the first pixel opening K1, the second pixel opening K2 and the third pixel opening K3 may satisfy the limitation <X41>, and do not satisfy the limitations <X42> and <X43>. That is, the orthogonal projection of the first pixel opening K1 on the base substrate 100 (not shown in the figure) is located within the orthogonal projection of the first filter opening L1 on the base substrate 100. The orthogonal projection of the second pixel opening K2 on the base substrate 100 is not located within the orthogonal projection of the second filter opening L2 on the base substrate 100. The orthogonal projection of the third pixel opening K3 on the base substrate 100 is not located within the orthogonal projection of the third filter opening L3 on the base substrate 100.

In an example N42, the first pixel opening K1, the second pixel opening K2 and the third pixel opening K3 may satisfy the limitation <X42>, and do not satisfy the limitations <X41> and <X43>. As for details, reference may be made to the above explanation.

In an example N43, the first pixel opening K1, the second pixel opening K2 and the third pixel opening K3 may satisfy the limitation <X43>, and do not satisfy the limitations <X41> and <X42>. As for details, reference may be made to the above explanation.

Example N44 is a combination of any two of the examples N41, N42 and N43.

Example N45 is a combination of the three examples N41, N42 and N43.

With continued reference to FIGS. 21 and 22, in some implementations, the first sub-pixel 610 is a red sub-pixel, the second sub-pixel 620 is a green sub-pixel, and the third sub-pixel 630 is a blue sub-pixel.

A ratio of an area of the first pixel opening K1 to an area of the first filter opening L1 is a first ratio. A ratio of an area of the second pixel opening K2 to an area of the second filter opening L2 is a second ratio. A ratio of an area of the third pixel opening K3 to an area of the third filter opening L3 is a third ratio. The second ratio is greater than the first ratio and less than the third ratio. With continued reference to FIGS. 21 and 22, some embodiments of the present disclosure provide a display panel DP. In the display panel DP, a size of the first filter opening L1 in the third direction E is a first filter size L11, a size of the first pixel opening K1 in the third direction E is a first pixel size K11, and the first filter size L11 is greater than the first pixel size K11. A size of the second filter opening L2 in the third direction E is a second filter size L21, a size of the second pixel opening K2 in the third direction E is a second pixel size K21, and the second filter size L21 is greater than the second pixel size K21. A size of the third filter opening L3 in the third direction E is a third filter size L31, a size of the third pixel opening K3 in the third direction E is a third pixel size K31, and the third filter size L31 is greater than the third pixel size K31.

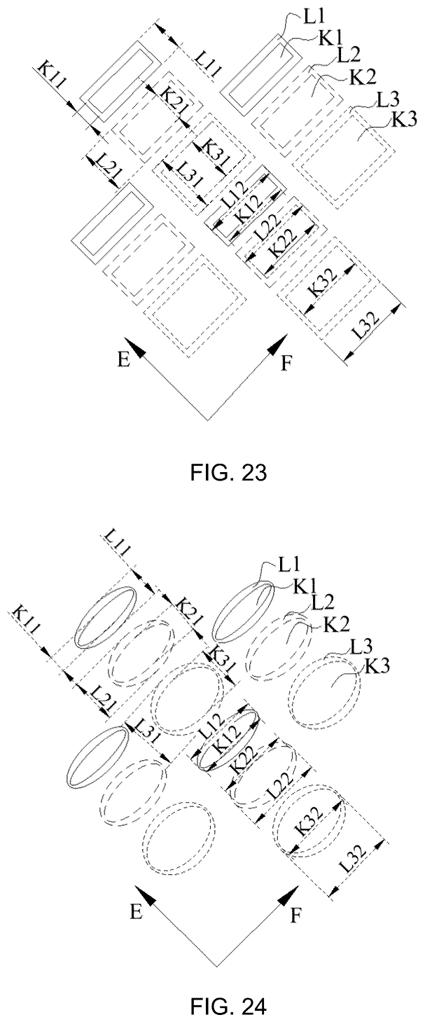

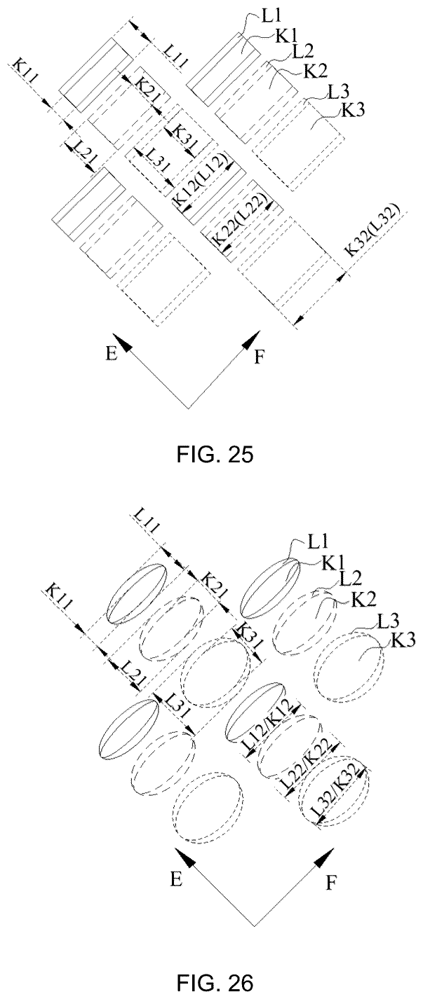

FIG. 23 is yet another alternative structural diagram of FIG. 19. FIG. 24 is another alternative structural diagram of FIG. 20. FIG. 25 is yet another alternative structural diagram of FIG. 19. FIG. 26 is yet another alternative structural diagram of FIG. 20.

Referring to FIGS. 23 to 26, in some possible implementations, the first filter opening L1, the second filter opening L2, the third filter opening L3, the first pixel opening K1, the second pixel opening K2, and the third pixel opening K3 satisfy at least one of the following limitations (i.e. conditions):
<X51>, a size of the first filter opening L1 in the fourth direction F is a fourth filter size L12; the fourth direction F and the third direction E intersect, for example, are perpendicular to each other; a size of the first pixel opening K1 in the fourth direction F is a fourth pixel size K12; the fourth filter size L12 is greater than or equal to the fourth pixel size K12; a difference between the first filter size L11 and the first pixel size K11 is greater than a difference between the fourth filter size L12 and the fourth pixel size K12;
<X52>, a size of the second filter opening L2 in the fourth direction F is a fifth filter size L22, and a size of the second pixel opening K2 in the fourth direction F is a fifth pixel size K22; the fifth filter size L22 is greater than or equal to the fifth pixel size K22; a difference between the second filter size L21 and the second pixel size K21 is greater than a difference between the fifth filter size L22 and the fifth pixel size K22; or
<X53>, a size of the third filter opening L3 in the fourth direction F is a sixth filter size L32; a size of the third pixel opening K3 in the fourth direction F is a sixth pixel size K32; the sixth filter size L32 is greater than or equal to the sixth pixel size K32; a difference between the third filter size L31 and the third pixel size K31 is greater than a difference between the sixth filter size L32 and the sixth pixel size K32.

As for the first filter opening L1, the second filter opening L2, the third filter opening L3, the first pixel opening K1, the second pixel opening K2 and the third pixel opening K3 that satisfy the limitations <X51>, <X52>, and <X53>, the following various examples are provided. In an example N51, the first filter opening L1, the second filter opening L2, the third filter opening L3, the first pixel opening K1, the second pixel opening K2, and the third pixel opening K3 may satisfy the limitation <X51>, but do not satisfy the limitations <X52> and <X53>. As for details, reference may be made to the above explanation.

In an example N52, the first filter opening L1, the second filter opening L2, the third filter opening L3, the first pixel opening K1, the second pixel opening K2, and the third pixel opening K3 may satisfy the limitation <X52>, but do not satisfy the limitations <X51> and <X53>. As for details, reference may be made to the above explanation.

In an example N53, the first filter opening L1, the second filter opening L2, the third filter opening L3, the first pixel opening K1, the second pixel opening K2, and the third pixel opening K3 may satisfy the limitation <X53>, but do not satisfy the limitations <X51> and <X52>. As for details, reference may be made to the above explanation.

Example N54 is a combination of any two of the examples N51, N52 and N53.

Example N55 is a combination of the three examples N51, N52 and N53.

It will be noted that, herein, the first filter size L11 and the fourth filter size L12 are both sizes of the lower end of the first filter opening L1. The second filter size L21 and the fifth filter size L22 are both sizes of the lower end of the second filter opening L2. The third filter size L31 and the sixth filter size L32 are both sizes of the lower end of the third filter opening L3. The first pixel size K11 and the fourth pixel size K12 are both sizes of the lower end of the first pixel opening K1. The second pixel size K21 and the fifth pixel size K22 are both sizes of the lower end of the second pixel opening K2. The third pixel size K31 and the sixth pixel size K32 are both sizes of the lower end of the third pixel opening K3.

Referring to FIG. 25, some embodiments of the present disclosure provide a display panel DP. In the display panel DP, in the case where the first filter opening L1 has the first filter size L11 and the fourth filter size L12, the second filter opening L2 has the second filter size L21 and the fifth filter size L22, the third filter opening L3 has the third filter size L31 and the sixth filter size L32, the first pixel opening K1 has the first pixel size K11 and the fourth pixel size K12, the second pixel opening K2 has the second pixel size K21 and the fifth pixel size K22, and the third pixel opening K3 have the third pixel size K31 and the sixth pixel size K32:
the difference between the first filter size L11 and the first pixel size K11, the difference between the second filter size L21 and the second pixel size K21, the difference between the third filter size L31 and the third pixel size K31, the difference between the fourth filter size L12 and the fourth pixel size K12, the difference between the fifth filter size L22 and the fifth pixel size K22, the difference between the sixth filter size L32 and the sixth pixel size K32 are each greater than or equal to 0 μm and less than or equal to 6 μm, such as 2 μm, 2.5 μm, 3 μm, 4 μm, 5 μm or 6 μm.

Referring to FIG. 25, some embodiments of the present disclosure provide a display panel DP. In the display panel DP, in the case where the first filter opening L1 has the first filter size L11 and the fourth filter size L12, the second filter opening L2 has the second filter size L21 and the fifth filter size L22, the third filter opening L3 has the third filter size L31 and the sixth filter size L32, the first pixel opening K1 has the first pixel size K11 and the fourth pixel size K12, the second pixel opening K2 has the second pixel size K21 and the fifth pixel size K22, and the third pixel opening K3 have the third pixel size K31 and the sixth pixel size K32:
the difference between the first filter size L11 and the first pixel size K11, the difference between the second filter size L21 and the second pixel size K21, the difference between the third filter size L31 and the third pixel size K31 are each in a range of 2 μm to 6 μm, such as 2 μm, 2.5 μm, 3 μm, 4 μm, 5 μm or 6 μm.

In some possible implementations, the difference between the fourth filter size L12 and the fourth pixel size K12, the difference between the fifth filter size L22 and the fifth pixel size K22, the difference between the sixth filter size L32 and the sixth pixel size K32 are each in a range of 0 μm to 4 μm, such as 0.5 μm, 1 μm, 1.5 μm, 2 μm, 3 μm, or 4 μm.

In some possible implementations, the difference between the first filter size L11 and the first pixel size K11, the difference between the second filter size L21 and the second pixel size K21, the difference between the third filter size L31 and the third pixel size K31 are each in a range of 2 μm to 6 μm, such as 2 μm, 2.5 μm, 3 μm, 4 μm, 5 μm or 6 μm.

In addition, the difference between the fourth filter size L12 and the fourth pixel size K12, the difference between the fifth filter size L22 and the fifth pixel size K22, the difference between the sixth filter size L32 and the sixth pixel size K32 are each in a range of 0 μm to 4 μm, such as 0.5 μm, 1 μm, 1.5 μm, 2 μm, 3 μm, or 4 μm.

In some embodiments, the plurality of filter openings L are arranged in multiple rows in the fourth direction F, and a row (e.g., each row) includes at least one filter opening unit (e.g., one filter opening unit, or multiple filter opening units). A filter opening unit includes a first filter opening L1, a second filter opening L2 and a third filter opening L3. A first filter opening L1, a second filter opening L2 and a third filter opening L3 in a row are arranged in sequence in the third direction E. An included angle between the third direction E and the second direction Y is in a range of 40° to 50°, such as one of 40°, 42°, 45°, 48°, 50°, etc. The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a base substrate;
a plurality of data lines arranged in a first direction and extending in a second direction, the first direction and the second direction intersecting;
a plurality of pixel driving circuits arranged in an array in the first direction and the second direction;
a pixel definition layer disposed on the base substrate, wherein the pixel definition layer includes a plurality of pixel openings, the plurality of pixel openings include first pixel openings, second pixel openings and third pixel openings; and
a plurality of pixels disposed on the base substrate, wherein the plurality of pixels are arranged in M rows and N columns, a row includes N pixels arranged in the first direction, a column includes M pixels arranged in the second direction, M≥2, and N≥2;
wherein a pixel includes a plurality of sub-pixels that emit light of different colors; the plurality of sub-pixels include: a first sub-pixel located at a first pixel opening, a second sub-pixel located at a second pixel opening, and a third sub-pixel located at a third pixel opening; the first sub-pixel, the second sub-pixel and the third sub-pixel are sequentially arranged in a third direction, the third direction and each of the first direction and the second direction intersecting;
each sub-pixel of the sub-pixels has a coupling point coupled to a pixel driving circuit; in the second direction, a distance between a geometric center of a coupling point of each of at least two sub-pixels that emit light of different colors and a respective pixel opening is different.

2. The display panel according to claim 1, wherein
the sub-pixel includes: a first electrode and a second electrode that are opposite to each other, and the first electrode of the sub-pixel is close to the base substrate;
the first electrode includes a connection portion and a body portion that are connected as a whole; a pixel opening exposes at least a part of the body portion; the coupling point of the sub-pixel is located in a region where the connection portion is located; and connection portions corresponding to at least two sub-pixels that emit light of different colors have different maximum sizes in the second direction.

3. The display panel according to claim 1, wherein
at least one of the first pixel opening, the second pixel opening and the third pixel opening is a pixel opening with a chamfered portion.

4. The display panel according to claim 3, wherein
the first pixel opening and the second pixel opening are each a pixel opening with a chamfered portion;
a chamfered portion of the first pixel opening and a chamfered portion of the second pixel opening are respectively located on sides, facing away from each other, of the first pixel opening and the second pixel opening.

5. The display panel according to claim 3, wherein
one of the first sub-pixel and the second sub-pixel is a red sub-pixel, and another of the first sub-pixel and the second sub-pixel is a green sub-pixel; and/or
the pixel opening with the chamfered portion has an axisymmetric structure, and a symmetry axis of the pixel opening with the chamfered portion is parallel to the third direction; and/or
the pixel opening with the chamfered portion further has a first sidewall and a second sidewall adjacent to the chamfered portion; the chamfered portion and the first sidewall form a first vertex angle, the chamfered portion and the second sidewall form a second vertex angle, and the first vertex angle is 0.9 to 1.1 times the second vertex angle.

6. (canceled)

7. (canceled)

8. The display panel according to claim 1, wherein
a shape of a lower end of the first pixel opening, the second pixel opening or the third pixel opening includes one or more shape types of rectangle, square, parallelogram, trapezoid, rhombus, pentagon, hexagon, octagon, ellipse, and circle; and/or
a shape of a lower end of the first pixel opening, the second pixel opening and the third pixel opening corresponding to the pixel belongs to a same shape type; and/or
an included angle between the third direction and the second direction is in a range of 40° to 50% %; and/or
an area of the first pixel opening is less than an area of the second pixel opening, and the area of the second pixel opening is less than an area of the third pixel opening.

9-11. (canceled)

12. The display panel according to claim 1, further comprising:
a light-shielding layer disposed on a side of the pixel definition layer away from the base substrate, wherein the light-shielding layer is provided therein with a plurality of filter openings, and the plurality of filter openings include first filter openings, second filter openings, and third filter openings; and
a plurality of filter patterns including first filter patterns, second filter patterns and third filter patterns, wherein a first filter pattern, a second filter pattern and a third filter pattern are located in a first filter opening, a second filter opening and a third filter opening, respectively; in a thickness direction of the base substrate, the first filter opening, the second filter opening and the third filter opening are directly opposite to the first pixel opening, the second pixel opening and the third pixel opening, respectively.

13. The display panel according to claim 12, wherein
an orthogonal projection of the first pixel opening on the base substrate is located within an orthogonal projection of the first filter opening on the base substrate; and/or
an orthogonal projection of the second pixel opening on the base substrate is located within an orthogonal projection of the second filter opening on the base substrate; and/or
an orthogonal projection of the third pixel opening on the base substrate is located within an orthogonal projection of the third filter opening on the base substrate.

14. The display panel according to claim 12, wherein
the first sub-pixel is a red sub-pixel, the second sub-pixel is a green sub-pixel, and the third sub-pixel is a blue sub-pixel;
a ratio of an area of the second pixel opening to an area of the second filter opening is greater than a ratio of an area of the first pixel opening to an area of the first filter opening, and is less than a ratio of an area of the third pixel opening to an area of the third filter opening.

15. The display panel according to claim 12, wherein
an orthogonal projection of the first pixel opening on the base substrate coincides with an orthogonal projection of the first filter opening on the base substrate; and/or
an orthogonal projection of the second pixel opening on the base substrate coincides with an orthogonal projection of the second filter opening on the base substrate; and/or
an orthogonal projection of the third pixel opening on the base substrate coincides with an orthogonal projection of the third filter opening on the base substrate.

16. The display panel according to claim 12, wherein
a size of the first filter opening in the third direction is a first filter size, a size of the first pixel opening in the third direction is a first pixel size, and the first filter size is greater than the first pixel size;
a size of the second filter opening in the third direction is a second filter size, a size of the second pixel opening in the third direction is a second pixel size, and the second filter size is greater than the second pixel size;
a size of the third filter opening in the third direction is a third filter size, a size of the third pixel opening in the third direction is a third pixel size, and the third filter size is greater than the third pixel size.

17. The display panel according to claim 16, wherein
a size of the first filter opening in a fourth direction is a fourth filter size, the fourth direction and the third direction intersecting; a size of the first pixel opening in the fourth direction is a fourth pixel size; the fourth filter size is greater than or equal to the fourth pixel size; a difference between the first filter size and the first pixel size is greater than a difference between the fourth filter size and the fourth pixel size; and/or
a size of the second filter opening in the fourth direction is a fifth filter size, and a size of the second pixel opening in the fourth direction is a fifth pixel size; the fifth filter size is greater than or equal to the fifth pixel size; a difference between the second filter size and the second pixel size is greater than a difference between the fifth filter size and the fifth pixel size; and/or
a size of the third filter opening in the fourth direction is a sixth filter size, and a size of the third pixel opening in the fourth direction is a sixth pixel size; the sixth filter size is greater than or equal to the sixth pixel size; a difference between the third filter size and the third pixel size is greater than a difference between the sixth filter size and the sixth pixel size.

18. The display panel according to claim 17, wherein
the first filter opening has the first filter size and the fourth filter size, the second filter opening has the second filter size and the fifth filter size, and the third filter opening has the third filter size and the six filter size, the first pixel opening has the first pixel size and the fourth pixel size, the second pixel opening has the second pixel size and the fifth pixel size, and the third pixel opening has the third pixel size and the sixth pixel size;;
the difference between the first filter size and the first pixel size, the difference between the second filter size and the second pixel size, the difference between the third filter size and the third pixel size, the difference between the fourth filter size and the fourth pixel size, the difference between the fifth filter size and the fifth pixel size, and the difference between the sixth filter size and the the sixth pixel size are each greater than or equal to 0 μm and less than or equal to 6 μm.

19. The display panel according to claim 17, wherein
the first filter opening has the first filter size and the fourth filter size, the second filter opening has the second filter size and the fifth filter size, and the third filter opening has the third filter size and the six filter size, the first pixel opening has the first pixel size and the fourth pixel size, the second pixel opening has the second pixel size and the fifth pixel size, and the third pixel opening has the third pixel size and the sixth pixel size;
the difference between the first filter size and the first pixel size, the difference between the second filter size and the second pixel size, and the difference between the third filter size and the third pixel size are each in a range of 2 μm to 6 μm; and/or
the difference between the fourth filter size and the fourth pixel size, the difference between the fifth filter size and the fifth pixel size, and the difference between the sixth filter size and the the sixth pixel size are each in a range of 0 μm to 4 μm.

20. The display panel according to claim 12, wherein
the plurality of filter openings are arranged in a plurality of rows in a fourth direction, a row includes at least one filter opening unit, and a filter opening unit includes one of the first filter openings, one of the second filter openings, and one of the third filter openings;
wherein a first filter opening, a second filter opening and a third filter opening in the row are sequentially arranged in the third direction, and an included angle between the third direction and the second direction is in a range of 40° to 50°.

21. The display panel according to claim 1, wherein
the display panel has a first display region and a second display region;
the plurality of pixels include a plurality of first pixels located in the first display region and a plurality of second pixels located in the second display region; a distribution density of the plurality of first pixels is greater than or equal to a distribution density of the plurality of second pixels.

22. The display panel according to claim 21, wherein
two first pixel openings, two second pixel openings and two third pixel openings corresponding to a first pixel and a second pixel satisfy at least one of the following limitations:
shapes of lower ends of the two first pixel openings belong to different shape types;
shapes of lower ends of the two second pixel openings belong to different shape types; or
shapes of lower ends of the two third pixel openings belong to different shape types.

23. The display panel according to claim 21, wherein
two first pixel openings, two second pixel openings and two third pixel openings corresponding to a first pixel and a second pixel satisfy at least one of the following limitations:
shapes of lower ends of the two first pixel openings belong to a same shape type;
shapes of lower ends of the two second pixel openings belong to a same shape type; or
shapes of lower ends of the two third pixel openings belong to a same shape type.

24. The display panel according to claim 21, wherein
a shape of a lower end of at least one of a first pixel opening, a second pixel opening and a third pixel opening corresponding to a second pixel includes an ellipse or a circle;
shapes of lower ends of a first pixel opening, a second pixel opening and a third pixel opening corresponding to a first pixel each include a polygon.

25. A display apparatus, comprising:
the display panel according to claim 1.
